(19) United States
(12) Patent Application Publication
(10) Pub. No.: US 2017/0141793 A1
(43) Pub. Date: May 18, 2017

(54) ERROR CORRECTION FOR NUCLEOTIDE DATA STORES

(71) Applicants: Microsoft Technology Licensing, LLC, Redmond, WA (US); University of Washington, Seattle, WA (US)

(72) Inventors: Karin Strauss, Seattle, WA (US); Siena Dumas Ang, Redmond, WA (US); Luis H. Ceze, Redmond, WA (US); James Bornholt, Redmond, WA (US)

(21) Appl. No.: 15/004,827

(22) Filed: Jan. 22, 2016

Related U.S. Application Data
(60) Provisional application No. 62/255,269, filed on Nov. 13, 2015.

(51) Int. Cl. H03M 13/05; G06F 19/28; H03M 13/00; G06F 19/16

(52) U.S. Cl. CPC H03M 13/05; G06F 19/16; G06F 19/28; H03M 13/611

(57) ABSTRACT

This disclosure provides techniques for adding error correction to information in a data store that encodes information as a sequence of bases in polynucleotides. Errors may be introduced through creation of the database (e.g., oligonucleotide synthesis) and/or reading information from the database (e.g., polynucleotide sequencing). Additional polynucleotides added to the database can provide error correction through redundancy. The sequence of polynucleotides that provide error correction may be designed by performing an invertible summary operation on information to be stored in the database. One example of an invertible summary operation is the exclusive or operation (XOR). This disclosure also provides techniques for storing metadata related to organization of a database and structure of information on polynucleotides within the database. Metadata may be encoded in polynucleotides and added to the data store. The polynucleotides holding metadata may be designed with unique primer sites so that the metadata can be selectively amplified and sequenced.

### CROSS-REFERENCE TO RELATED APPLICATION

The present application claims the benefit of U.S. Provisional Patent Application No. 62/255,269 filed Nov. 13, 2015, which is incorporated herein by reference in its entirety as if fully set forth herein.

### BACKGROUND

Much of the world's data today is stored on magnetic and optical media. Tape technology has recently seen significant density improvements with single tape cartridges storing 185 GB, and is the densest form of storage available commercially today, at about 10 GB/mm³. Recent research reported feasibility of optical discs capable of storing 1 PB, yielding a density of about 100 GB/mm³. Despite this improvement, storing a zettabyte (2⁷⁰ bytes or a billion terabytes) of data would still take many millions of units, and use significant physical space. But storage density is only one aspect of suitability for archival use; durability is also important. Rotating disks are rated for 3-5 years, and tape is rated for 10-30 years. Long-term archival storage requires data refreshes, both to replace faulty units and to refresh technology.

Demand for data storage is growing exponentially, but the capacity of existing storage media is not keeping up. Polymers of deoxyribose nucleic acid (DNA) are capable of storing information at high density. The theoretical density limit is 1 exabyte/mm³ (10⁹ GB/mm³). Less than 100 grams of DNA could store all the human-made data in the world today. DNA is also long lasting, with an observed half-life of over 500 years under certain storage conditions. Thus, DNA is appealing as an information storage technology because of its high information density and longevity. A further advantage of DNA storage media is its continued relevance. Operating systems and standards for storage media will change potentially making data on older storage systems inaccessible. But DNA-based storage has the benefit of eternal relevance: as long as there is DNA-based life, there will be strong reasons to maintain technology that is able to read and manipulate DNA.

The write process for DNA storage maps digital data into DNA nucleotide sequences by synthesizing (manufacturing) an arbitrary DNA sequence that contains the same data as the digital data. The synthetic molecules are then stored. Reading the data involves sequencing the DNA molecule and decoding it back to the original digital data. Progress in DNA storage has been rapid: in 1999, the state-of-the-art in DNA-based storage was able to encode and recover a 23-character message; in 2013, researchers successfully recovered a 739 kB message. This improvement of almost 2×/year has been fueled by exponential reduction in cost and time for synthesis and sequencing.

Although it has several advantages, a DNA storage system must overcome several challenges. First, DNA synthesis and sequencing is far from perfect, with error rates of up to 1% per nucleotide. Sequences can also degrade while stored, further compromising data integrity. A viable DNA storage system will include an encoding scheme that can tolerate errors by providing for error correction.

### SUMMARY

This Summary is provided to introduce a selection of concepts in a simplified form that are further described below in the Detailed Description. This Summary is not intended to identify key features or essential features of the claimed subject matter nor is it intended to be used to limit the scope of the claimed subject matter.

Binary data of the kind currently used by computers to store text files, audio files, video files, software and the like can be represented as a series of nucleic acids in a polynucleotide (i.e., DNA or RNA). There are multiple techniques for representing the 0 and 1 of binary data as a series of nucleotides. Once the binary data has been mapped to a specific polynucleotide sequence additional information that serves to identify the binary data (e.g., identifying which digital file the data came from, providing addressing information so that different portions of the file can be reassembled, etc.) can be appended to the binary data. This additional identifying information is also represented as a polynucleotide sequence. Furthermore, one or more primer target sequences can be added to one or both of the ends of the polynucleotide sequence. The primer target sequences provide “handles” for polynucleotide primers to anneal and this enables manipulation of the resultant polynucleotide molecule. Thus, in one implementation the resulting polynucleotide sequence includes a payload which is the portion representing the original binary data, an identifier region that provides information about the binary data, and one or more primer target sequences.

Once this polynucleotide sequence is designed, conventional oligonucleotide synthesis technology may be used to synthesize a polynucleotide molecule with the desired sequence. This polynucleotide, along with many others, may be combined into a storage library or data store. Some of the other polynucleotide molecules may be identical to each other. And others will contain different information—either different portions of the same original binary data or binary data corresponding to a different file.

Error correction can be provided by adding additional polynucleotide molecules that partially summarize one or more of the polynucleotides that contain payloads derived from the original binary data. Providing additional polynucleotides that summarizes information from other polynucleotides provides redundancy and this redundancy makes it easier to obtain uncorrupted data from the data store. If data in a given polynucleotide molecule is lost or corrupted, the summary information may be used to regenerate the missing data. This makes error correction possible.

The polynucleotide sequences used for error correction may be generated by performing an invertible summary operation on the data stored in one or more of the payloads. The invertible summary operation has the property of creating a partial summary sequence that, when combined with part of the input data is able to generate the remaining portion of the input data. For example, if an error-correction sequence is generated from two payload sequences by an invertible summary operation, then performing that same invertible summary operation on the error-correction sequence with one of the two payload sequences will yield the other payload sequence. Thus, this operation is invertible because it is used both to create the error-correction sequence and to regenerate the original data from the error-correction sequence. This operation creates a partial summary because the error-correction sequence without at least one of the original payload sequences is unable to regenerate the original data. One example of an invertible summary operation is the exclusive or (XOR) operation.

### DESCRIPTION OF THE DRAWINGS

The Detailed Description is set forth with reference to the accompanying figures. In the figures, the left-most digit(s) of a reference number identifies the figure in which the reference number first appears. The use of the same reference numbers in different figures indicates similar or identical items.

FIG. 1 shows an illustrative architecture for interacting with a DNA storage library.

FIG. 2 shows an illustrative computing device for interacting with a DNA storage library.

FIG. 3 shows an illustrative representation of binary data being converted into a DNA representation of the data and included in a synthetic DNA molecule.

FIG. 4 shows illustrative schematics of three different invertible summary operations that summarize information contained in polynucleotide molecules.

FIG. 5 shows an illustrative schematic of a collection of polynucleotide molecules which include molecules encoding three different types of information.

FIG. 6 shows an illustrative process for generating and using a DNA storage library.

FIG. 7 show an illustrative process for designing polynucleotides that encode binary data, error-correction sequences, and metadata.

FIG. 8 is a graph showing the effect of sequencing depth on decoding accuracy for two different error-correction techniques.

FIG. 9 is a graph showing a relationship between reliability of encoded data and storage density for two different sequencing depths and three different error-correction techniques.

### DETAILED DESCRIPTION

Naturally occurring DNA consists of four types of nucleotides: adenine (A), cytosine (C), guanine (G), and thymine (T). A DNA strand, or oligonucleotide, is a linear sequence of these nucleotides. The two ends of a DNA strand, referred to as the 5′ and 3′ ends, are chemically different. DNA sequences are conventionally represented starting with the 5′ nucleotide end. The interactions between different strands are predictable based on sequence: two single strands can bind to each other and form a double helix if they are complementary: A in one strand aligns with T in the other, and likewise for C and G. The two strands in a double helix have opposite directionality (5′ end attached to the other strand's 3′ end), and thus the two sequences are the “reverse complement” of each other. Two strands do not need to be fully complementary to bind to one another. Such partial complementarity is useful for applications in DNA nanotechnology and other fields, but can also result in undesired “crosstalk” between sequences in complex reaction mixtures containing many sequences. Ribonucleic acid (RNA) has a similar structure to DNA and naturally occurring RNA consists of the four nucleotides A, C, G, and uracil (U) instead of T. Discussions in this disclosure may mention only DNA for the sake of brevity and readability, but RNA may be used in place of or in combination with DNA.

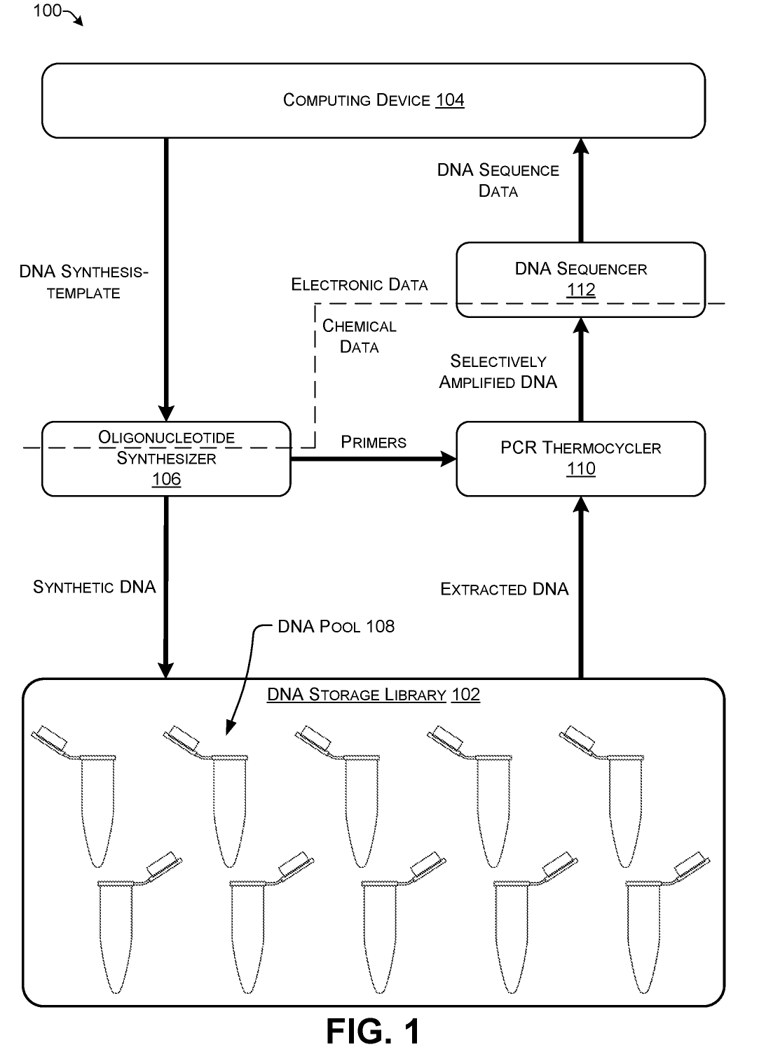

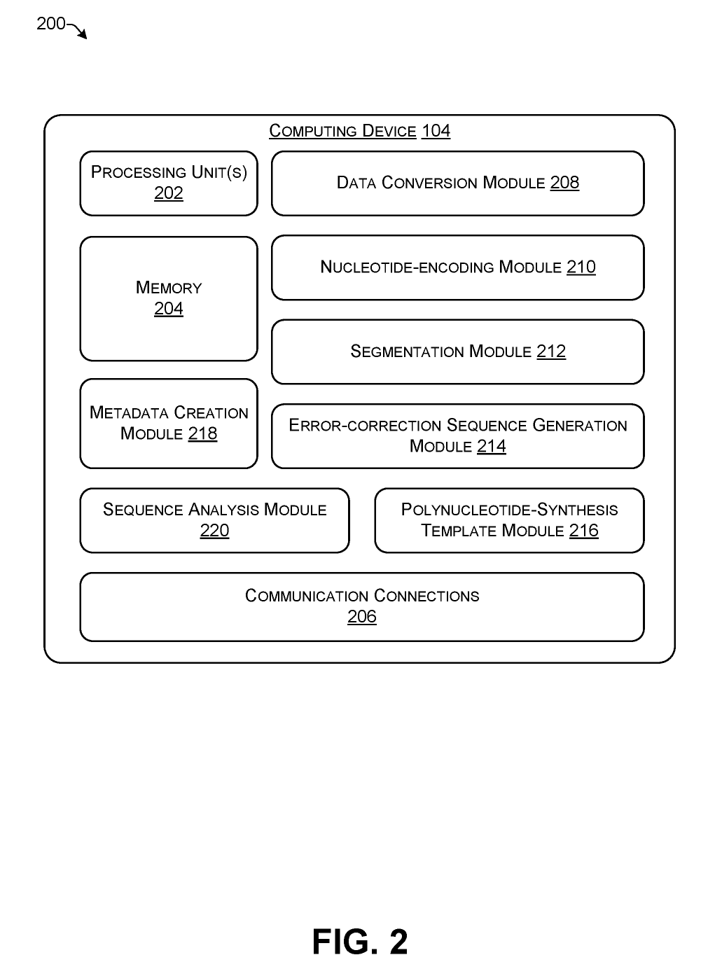

FIG. 1 shows an illustrative architecture 100 for implementing and interacting with a DNA Storage Library 102. Computing device 104 may be a computer that uses electricity and electrical charges to processes information represented in digital form. The computing device 104 is described in additional detail below as part of the description of FIG. 2. The computing device 104 may provide DNA sequences as data (i.e., a string of letters representing an order of nucleotide bases) that are used as DNA-synthesis templates that instruct an oligonucleotide synthesizer 106 to chemically synthesize a DNA molecule nucleotide by nucleotide. Artificial synthesis of DNA allows for creation of DNA molecules with arbitrary series of the bases in which individual monomers of the bases are assembled together into a polymer that represents information in a manner analogous to 0 and 1 in computers. Because binary information is recorded using base-two (i.e., 0 and 1) and there are four different naturally occurring DNA nucleotides (i.e., A, G, C, and T) there may be conversion from a base-two numeral system to a base-three (ternary) or base-four (quaternary) numeral system. Conversion between different numeral systems is discussed below. The oligonucleotide synthesizer 106 may be any oligonucleotide synthesizer using any recognized technique for DNA synthesis. Oligonucleotide synthesizer and methods for using oligonucleotide synthesizers are known in the art.

The term “oligonucleotide” as used herein is defined as a molecule including two or more nucleotides. Oligonucleotides include probes and primers. Oligonucleotides used as probes or primers may also include nucleotide analogues such as phosphorothioates, alkylphosphorothioates, peptide nucleic acids, or intercalating agents. The introduction of these modifications may be advantageous in order to positively influence characteristics such as hybridization kinetics, reversibility of the hybrid-formation, stability of the oligonucleotide molecules, and the like.

The coupling efficiency of a synthesis process is the probability that a nucleotide binds to an existing partial strand at each step of the process. Although the coupling efficiency for each step can be higher than 99%, this small error still results in an exponential decrease of product yield with increasing length and limits the size of oligonucleotides that can be efficiently synthesized at present to about 200 nucleotides.

In practice, synthesis of a given sequence starts with a large number of start sites (on the order of 10⁸) and results in many truncated byproducts (the dominant error in DNA synthesis), in addition to many copies of the full length target sequence. Thus, despite errors in synthesizing any specific strand, a given synthesis batch will usually produce many perfect strands. Moreover, modern array synthesis techniques can synthesize complex pools of up to 10⁵ oligonucleotides in parallel on a single chip. Thus, multiple DNA molecules can be synthesized with particular orders of the four DNA bases and encode large amounts of information.

Synthetic DNA produced by the oligonucleotide synthesizer 106 may be transferred to the DNA storage library 102. The basic unit of DNA storage is a DNA strand that is roughly 100-200 nucleotides given the limits of current oligonucleotide synthesis technology. This length will increase with advances in oligonucleotide synthesis. The DNA Storage Library 102 may contain one or more DNA pools 108. Strands of DNA may be placed into separate DNA pools 108 when a first DNA pool 108 is full. The DNA strands may also be organized based on informational content so that DNA strands are grouped into a same DNA pool 108 due to similar informational content or separated into different pools based on differences in informational content. The DNA strands stored in the DNA pools 108 have stochastic spatial organization and do not permit structured addressing unlike electronic storage media. Therefore, address information is embedded into the data stored in a DNA strand. This way, after sequencing, it is possible to reassemble the original data from the pieces of data stored on multiple separate DNA strands.

DNA strands are generally most accessible for manipulation by bio-technological techniques when the DNA is stored in a liquid solution. Thus, a DNA Storage Library 102 can be implemented as a chamber filled with liquid, in many implementations water, and thousands, millions, or more individual DNA molecules separated into one or more DNA pools 108.

Besides being in a liquid suspension, the DNA strands in the DNA Storage Library 102 may be present in a glassy (or vitreous) state, as lyophilized product, or other format. The structure of the DNA pools 108 may be implemented as any type of mechanical, biological, or chemical arrangement which holds a volume of liquid including DNA to a physical location. Storage may also be in a non-liquid form such as a solid bead or by encapsulation. Examples of DNA storage techniques are discussed by Grass, et al. (Michela Puddu, Wendelin J. Stark, and Robert N. Grass. Silica Microcapsules for Long-Term, Robust, and Reliable Room Temperature RNA Preservation. Advanced Healthcare Materials, 2015, 4, 9, 1332). For example, a single flat surface having a droplet present thereon, with the droplet held in part by surface tension of the liquid, even though not fully enclosed within a container, is one implementation of a DNA pool 108. The DNA pool 108 may include single-stranded DNA (ssDNA), double-stranded DNA (dsDNA), single-stranded RNA (ssRNA), double-stranded RNA (dsRNA), or any combination including use of unnatural bases.

DNA extracted from a DNA pool 108 in the DNA Storage Library 102 is amplified by a PCR thermocycler 110 to make a large number of identical copies of the DNA strand. Polymerase chain reaction (PCR) is a method for amplifying the concentration of selected sequences of DNA within a pool. Any of several methods can be used to amplify a target nucleic acid from a sample. The term “amplifying” which typically refers to an “exponential” increase in the number of copies of the target nucleic acid is used herein to describe both linear and exponential increases in the numbers of a select target sequence of nucleic acid. The term “amplification reaction mixture” refers to an aqueous solution comprising the various reagents used to amplify a target nucleic acid.

A PCR reaction has three main components: the template, sequencing primers, and enzymes. The template is a single- or double-stranded molecule containing the (sub)sequence that will be amplified. The DNA sequencing primers are short synthetic strands that define the beginning and end of the region to be amplified. The enzymes include polymerases and thermostable polymerases such as DNA polymerase, RNA polymerase and reverse transcriptase. The enzymes create double-stranded DNA from a single-stranded template by “filling in” complementary nucleotides one by one through addition of nucleoside triphosphates, starting from a primer bound to that template. PCR happens in “cycles,” each of which doubles the number of templates in a solution. The process can be repeated until the desired number of copies is created. The DNA sequencing primers may be produced by the oligonucleotide synthesizer 106. PCR may also be used during the sequencing process to attach sequencing adapters to the DNA strands. A sequencing adapter is a known string of 20-30 nucleotides that will bind to a sequencing flow cell, effectively anchoring the strand so that it can be sequenced.

A variety of PCR techniques are known and can be used in the assays described herein. PCR techniques are typically used for the amplification of at least a portion of an oligonucleotide. The sample to be tested for the presence of an analyte-specific sequence is contacted with the first and second oligonucleotide primers; a nucleic acid polymerase; and nucleotide triphosphates corresponding to the nucleotides to be added during PCR. The natural base nucleotide triphosphates include dATP, dCTP, dGTP, dTTP, and dUTP. Nucleoside triphosphates of non-standard bases can also be added, if desired or needed. Suitable polymerases for PCR are known and include, for example, thermostable polymerases such as native and altered polymerases of Thermus species, including, but not limited to Thermus aquaticus (Taq), Thermus flavus (Tfl), and Thermus thermophilus (Tth), as well as the Klenow fragment of DNA polymerase I and the HIV-1 polymerase.

An additional type of PCR is Droplet Digital™ PCR (ddPCR™) (Bio-Rad Laboratories, Hercules, Calif.). ddPCR technology uses a combination of microfluidics and surfactant chemistry to divide PCR samples into water-in-oil droplets. The droplets support PCR amplification of the target template molecules they contain and use reagents and workflows similar to those used for most standard Taqman probe-based assays. Following PCR, each droplet is analyzed or read in a flow cytometer to determine the fraction of PCR-positive droplets in the original sample. These data are then analyzed using Poisson statistics to determine the target concentration in the original sample. See Bio-Rad Droplet Digital™ (ddPCR™) PCR Technology.

While ddPCR™ is one PCR approach, other sample partition PCR methods based on the same underlying principles may also be used. The partitioned nucleic acids of a sample can be amplified by any suitable PCR methodology that can be practiced within spdPCR. Illustrative PCR types include allele-specific PCR, assembly PCR, asymmetric PCR, endpoint PCR, hot-start PCR, in situ PCR, intersequence-specific PCR, inverse PCR, linear after exponential PCR, ligation-mediated PCR, methylation-specific PCR, miniprimer PCR, multiplex ligation-dependent probe amplification, multiplex PCR, nested PCR, overlap-extension PCR, polymerase cycling assembly, qualitative PCR, quantitative PCR, real-time PCR, single-cell PCR, solid-phase PCR, thermal asymmetric interlaced PCR, touchdown PCR, universal fast walking PCR, etc. Ligase chain reaction (LCR) may also be used.

Amplification by the PCR thermocycler 110 provides a sufficient number of copies of a DNA strand for a DNA sequencer 112 to determine a sequence of the nucleotides present in the DNA strand. The DNA sequencer 106 reads the order of the DNA bases in a given DNA molecule. Sequencing is error-prone, but as with synthesis, sequencing typically produces many accurate reads of each strand. DNA sequencing includes any method or technology that is used to determine the order of the four bases—A, G, C, and T—in a strand of DNA.

Multiple techniques for sequencing nucleic acids are known to those skilled in the art. DNA sequencing techniques include classic dideoxy sequencing reactions (Sanger method) using labeled terminators or primers and gel separation in slab or capillary electrophoresis. In one implementation, next generation (NextGen) sequencing platforms are advantageously used in the practice of the invention. NextGen sequencing refers to any of a number of post-classic Sanger type sequencing methods which are capable of high throughput, multiplex sequencing of large numbers of samples simultaneously. Current NextGen sequencing platforms are capable of generating reads from multiple distinct nucleic acids in the same sequencing run. Throughput is varied, with 100 million bases to 600 giga bases per run, and throughput is rapidly increasing due to improvements in technology. The principle of operation of different NextGen sequencing platforms is also varied and can include: sequencing by synthesis using reversibly terminated labeled nucleotides, pyrosequencing, 454 sequencing, allele specific hybridization to a library of labeled oligonucleotide probes, sequencing by synthesis using allele specific hybridization to a library of labeled clones that is followed by ligation, real-time monitoring of the incorporation of labeled nucleotides during a polymerization step, polony sequencing, single molecule real-time sequencing, nanopore sequencing, and SOLiD™ sequencing.

454 sequencing involves two steps. In the first step, any long DNA strands present in a sample are sheared into fragments of approximately 300-800 base pairs, and the fragments are blunt ended. Oligonucleotide adaptors are then ligated to the ends of the fragments. The adaptors serve as primers for amplification and sequencing of the fragments. The fragments can be attached to DNA capture beads, e.g., streptavidin-coated beads using, e.g., Adaptor B, which contains 5′-biotin tag. The fragments attached to the beads are PCR amplified within droplets of an oil-water emulsion. The result is multiple copies of clonally amplified DNA fragments on each bead. In the second step, the beads are captured in wells (pico-liter sized). Pyrosequencing is performed on each DNA fragment in parallel. Addition of one or more nucleotides generates a light signal that is recorded by a CCD camera in a sequencing instrument. The signal strength is proportional to the number of nucleotides incorporated. Pyrosequencing makes use of pyrophosphate (PPi) which is released upon nucleotide addition. PPi is converted to ATP by ATP sulfurylase in the presence of adenosine 5′ phosphosulfate. Luciferase uses ATP to convert luciferin to oxyluciferin, and this reaction generates light that is detected and analyzed.

A sequencing technique that can be used is Helicos True Single Molecule Sequencing (tSMS). In the tSMS technique, a DNA sample is cleaved into strands of approximately 100 to 200 nucleotides, and a polyA sequence is added to the 3′ end of each DNA strand. Each strand is labeled by the addition of a fluorescently labeled adenosine nucleotide. The DNA strands are then hybridized to a flow cell, which contains millions of oligo-T capture sites that are immobilized to the flow cell surface. The templates can be at a density of about 100 million templates/cm². The flow cell is then loaded into an instrument, e.g., HeliScope™ sequencer, and a laser illuminates the surface of the flow cell, revealing the position of each template. A CCD camera can map the position of the templates on the flow cell surface. The template fluorescent label is then cleaved and washed away. The sequencing reaction begins by introducing a DNA polymerase and a fluorescently labeled nucleotide. The oligo-T nucleic acid serves as a primer. The polymerase incorporates the labeled nucleotides to the primer in a template directed manner. The polymerase and unincorporated nucleotides are removed. The templates that have directed incorporation of the fluorescently labeled nucleotide are detected by imaging the flow cell surface. After imaging, a cleavage step removes the fluorescent label, and the process is repeated with other fluorescently labeled nucleotides until the desired read length is achieved. Sequence information is collected with each nucleotide addition step.

Another example of a DNA sequencing technique that can be used is SOLiD™ technology (Applied Biosystems). In SOLiD™ sequencing, genomic DNA is sheared into fragments, and adaptors are attached to the 5′ and 3′ ends of the fragments to generate a fragment library. Alternatively, internal adaptors can be introduced by ligating adaptors to the 5′ and 3′ ends of the fragments, circularizing the fragments, digesting the circularized fragment to generate an internal adaptor, and attaching adaptors to the 5′ and 3′ ends of the resulting fragments to generate a mate-paired library. Next, clonal bead populations are prepared in microreactors containing beads, primers, template, and PCR components. Following PCR, the templates are denatured and beads are enriched to separate the beads with extended templates. Templates on the selected beads are subjected to a 3′ modification that permits bonding to a glass slide.

Another example of a sequencing technology that can be used is SOLEXA® sequencing (Illumina). SOLEXA® sequencing is based on the amplification of DNA on a solid surface using fold-back PCR and anchored primers. Genomic DNA is fragmented, and adapters are added to the 5′ and 3′ ends of the fragments. DNA fragments that are attached to the surface of flow cell channels are extended and bridge amplified. The fragments become double stranded, and the double stranded molecules are denatured. Multiple cycles of the solid-phase amplification followed by denaturation can create several million clusters of approximately 1,000 copies of single-stranded DNA molecules of the same template in each channel of the flow cell. Primers, DNA polymerase and four fluorophore-labeled, reversibly terminating nucleotides are used to perform sequential sequencing. After nucleotide incorporation, a laser is used to excite the fluorophores, and an image is captured and the identity of the first base is recorded. The 3′ terminators and fluorophores from each incorporated base are removed and the incorporation, detection, and identification steps are repeated.

Another example of a sequencing technology that can be used includes the single molecule, real-time (SMRT™) technology of Pacific Biosciences. In SMRT™, each of the four DNA bases is attached to one of four different fluorescent dyes. These dyes are phospholinked. A single DNA polymerase is immobilized with a single molecule of template single stranded DNA at the bottom of a zero-mode waveguide (ZMW). A ZMW is a confinement structure which enables observation of incorporation of a single nucleotide by DNA polymerase against the background of fluorescent nucleotides that rapidly diffuse in an out of the ZMW (in microseconds). It takes several milliseconds to incorporate a nucleotide into a growing strand. During this time, the fluorescent label is excited and produces a fluorescent signal, and the fluorescent tag is cleaved off. Detection of the corresponding fluorescence of the dye indicates which base was incorporated. The process is repeated.

Another example of a sequencing technique that can be used is nanopore sequencing. A nanopore is a small hole, of the order of 1 nanometer in diameter. Immersion of a nanopore in a conducting fluid and application of a potential across it results in a slight electrical current due to conduction of ions through the nanopore. The amount of current which flows is sensitive to the size of the nanopore. As a DNA molecule passes through a nanopore, each nucleotide on the DNA molecule obstructs the nanopore to a different degree. Thus, the change in the current passing through the nanopore as the DNA molecule passes through the nanopore represents a reading of the DNA sequence.

Another example of a sequencing technique that can be used involves using a chemical-sensitive field effect transistor (chemFET) array to sequence DNA. In one example of the technique, DNA molecules can be placed into reaction chambers, and the template molecules can be hybridized to a sequencing primer bound to a polymerase. Incorporation of one or more triphosphates into a new nucleic acid strand at the 3′ end of the sequencing primer can be detected by a change in current by a chemFET. An array can have multiple chemFET sensors. In another example, single nucleic acids can be attached to beads, and the nucleic acids can be amplified on the bead, and the individual beads can be transferred to individual reaction chambers on a chemFET array, with each chamber having a chemFET sensor, and the nucleic acids can be sequenced.

Another example of a sequencing technique that can be used involves using an electron microscope. In one example of the technique, individual DNA molecules are labeled using metallic labels that are distinguishable using an electron microscope. These molecules are then stretched on a flat surface and imaged using an electron microscope to measure sequences.

The DNA sequencer 112 provides output in electronic format that can be manipulated by the computing device 104. The oligonucleotide synthesizer 106 discussed above performs a conversion of data from electronic to chemical form. The DNA sequencer 112 performs a complementary conversion of data from chemical to electronic form.

In one implementation, portions of the architecture 100 may be implemented by a microfluidics system. Microfluidics is a multidisciplinary field intersecting engineering, physics, chemistry, biochemistry, nanotechnology, and biotechnology, with practical applications to the design of systems in which small volumes of fluids will be handled. Typically, fluids are moved, mixed, separated, or otherwise processed. Numerous applications employ passive fluid control techniques like capillary forces. In some applications, external actuation is additionally used for a directed transport of the media. Examples of external actuation include rotary drives applying centrifugal forces for the fluid transport on the passive chips.

Microfluidics systems and methods to divide a bulk volume into partitions include emulsification, generation of “water-in-oil” droplets, and generation of monodisperse droplets as well as using channels, valves, and pumps. Partitioning methods can be augmented with droplet manipulation techniques, including electrical (e.g., electrostatic actuation, dielectrophoresis), magnetic, thermal (e.g., thermal Marangoni effects, thermocapillary), mechanical (e.g., surface acoustic waves, micropumping, peristaltic), optical (e.g., opto-electrowetting, optical tweezers), and chemical means (e.g., chemical gradients). In some embodiments, a droplet microactuator is supplemented with a microfluidics platform (e.g. continuous flow components). Some implementations of microfluidics systems use a droplet microactuator. A droplet microactuator can be capable of effecting droplet manipulation and/or operations, such as dispensing, splitting, transporting, merging, mixing, agitating, and the like.

Active microfluidics refers to the defined manipulation of the working fluid by active (micro) components such as micropumps or micro valves. Micro pumps supply fluids in a continuous manner or are used for dosing. Micro valves determine the flow direction or the mode of movement of pumped liquids. Often processes which are normally carried out in a lab are miniaturized on a single chip in order to enhance efficiency and mobility as well as reducing sample and reagent volumes. For example, the oligonucleotide synthesizer 106, the DNA Storage Library 102, the PCR thermocycler 110, and the DNA sequencer 112 may implemented in whole or part using microfluidics.

FIG. 2 shows an illustrative diagram 200 of the computing device 104 shown in FIG. 1. The computing device 104 may contain one or more processing unit(s) 202 and memory 204 both of which may be distributed across one or more physical or logical locations. The processing unit(s) 202 may include any combination of central processing units (CPUs), graphical processing units (GPUs), single core processors, multi-core processors, application-specific integrated circuits (ASICs), programmable circuits such as Field Programmable Gate Arrays (FPGA), and the like. One or more of the processing unit(s) 202 may be implemented in software and/or firmware in addition to hardware implementations. Software or firmware implementations of the processing unit(s) 202 may include computer- or machine-executable instructions written in any suitable programming language to perform the various functions described. Software implementations of the processing unit(s) 202 may be stored in whole or part in the memory 204.

Alternatively, or in addition, the functionally of the computing device 104 can be performed, at least in part, by one or more hardware logic components. For example, and without limitation, illustrative types of hardware logic components that can be used include Field-programmable Gate Arrays (FPGAs), Application-specific Integrated Circuits (ASICs), Application-specific Standard Products (ASSPs), System-on-a-chip systems (SOCs), Complex Programmable Logic Devices (CPLDs), etc.

Computing device 104 may be connected to other devices and/or a network through one or more communication connections 206 for receiving and sending information. The communication connections 206 may be implemented as wired connections, wireless connections, or both. A wired connection may include one or more wires or cables physically connecting the computing device 104 to another device. For example, the wired connection may be created by a headphone cable, a telephone cable, a SCSI cable, a USB cable, an Ethernet cable, or the like. A wireless connection may be created by radio waves (e.g., any version of Bluetooth, ANT, Wi-Fi IEEE 802.11, etc.), infrared light, or the like.

The communication connections 206 may include direct connections to one or more other devices (e.g. the oligonucleotide synthesizer 106, the DNA sequencer 112, the PCR thermocycler 110, a microfluidics system, etc.) without the presence of an intervening network. The communication connections 206 may include network connections to one or more different networks. The network(s) may be implemented as any type of communications network such as a local area network, a wide area network, a mesh network, and ad hoc network, a peer-to-peer network, the Internet, a cable network, a telephone network, and the like.

The computing device 104 may be a supercomputer, a network server, a desktop computer, a notebook computer, a collection of server computers such as a server farm, a cloud computing system that uses processing power, memory, and other hardware resources distributed across multiple geographic locations, or the like. The computing device 104 may include one or more input/output components(s) such as a keyboard, a pointing device, a touchscreen, a microphone, a camera, a display, a speaker, a printer, and the like.

Memory 204 of the computing device 104 may include removable storage, non-removable storage, local storage, and/or remote storage to provide storage of computer-readable instructions, data structures, program modules, and other data. The memory 204 may be implemented as computer-readable media. Computer-readable media includes at least two types of media: computer-readable storage media and communications media. Computer-readable storage media includes volatile and non-volatile, removable and non-removable media implemented in any method or technology for storage of information such as computer-readable instructions, data structures, program modules, or other data. Computer-readable storage media includes, but is not limited to, RAM, ROM, EEPROM, flash memory or other memory technology, CD-ROM, digital versatile disks (DVD) or other optical storage, magnetic cassettes, magnetic tape, magnetic disk storage or other magnetic storage devices, or any other non-transmission medium that can be used to store information for access by a computing device.

In contrast, communications media may embody computer-readable instructions, data structures, program modules, or other data in a modulated data signal, such as a carrier wave, or other transmission mechanism. As defined herein, computer-readable storage media and communications media are mutually exclusive.

The computing device 104 includes multiple modules that may be implemented as instructions stored in the memory 204 for execution by processing unit(s) 202 and/or implemented, in whole or in part, by one or more hardware logic components or firmware.

A data conversion module 208, converts binary data into a different data representation. Current electronic storage media store raw bits. The storage device abstracts the physical media, which could be magnetic state, or the charge in a capacitor, or the stable state of a flip-flop, and presents to the storage hierarchy raw digital data. In a similar way, the abstraction of DNA storage is the nucleotide: though a nucleotide is an organic molecule consisting of several atoms and a sugar, the abstraction of DNA storage is as a contiguous string of quaternary (base-4) numerals.

Because polynucleotides store information using quaternary (base-4) digits (i.e., AGCT for DNA and AGCU for RNA), one way of using polynucleotides to store binary data (base-2) involves mapping from 0 and 1 to a set of 4 bases (i.e., bits to quats). Thus, a string of binary data may be mapped to a string of quaternary data. For example, the binary string 01110001 maps to the base-4 string 1301. Thus, in one implementation the data conversion module 208 may convert base-2 data into base-4 data.

Binary data may also be converted to base-3 data by using only three of the possible nucleotides. Because base 3 is not a multiple of base 2, mapping directly between the bases can reduce storage density: 6 ternary digits (“trits”) (3⁶=729) can store 9 binary digits (“bits”) of data (2⁹=512), but waste 729−512=217 possible states. The waste of storage states may be reduced and storage density increased by using base 2 to base 3 mapping at a ratio of other than 1 to 1. For example, 3 bits may be encoded using 2 trits (3²=9 states used to store 2³=8 states wasting 1), 6 bits may be encoded using 4 trits (3⁴=81 states used to store 2⁶=64 states wasting 17), or a Huffman code that maps 1 bit to 5 or 6 trits may also be used. Other techniques for efficient mapping between binary digits and ternary digits will be apparent to one of ordinary skill in the art. The ternary digits may then be represented as nucleotide bases as described below.

A nucleotide coding module 210, generates a sequence of amino acids representing the data received from the data conversion module 208. The four bases may be represented by the numerals 0, 1, 2, and 3 (e.g., 0=A, 1=G, 2=C, 3=T or U). Quaternary data may be correlated to nucleotide bases. For example, the nucleotide coding module 210 may convert the base-4 string 1301 to the DNA sequence GTAG.

However, actual polynucleotides, rather than digital representations of the information encoded within, are prone to a wide variety of errors such as mutations, insertions, and deletions of nucleotides that may result from synthesis, sequencing, and degradation. One source of errors in sequencing of polynucleotides are homopolymers or repetitions of the same nucleotide such as AAA. Thus, while repeats of base-four digits are not a problem for computers, it may be desirable to generate a nucleotide sequence that avoids homopolymers.

Nucleotide coding module 210 may convert base-3 data into a series of nucleotides using a rotating code to reduce homopolymers. Because there are four possible nucleotide options and only three possibilities for a base-3 digit, a rotating code that associates a ternary digit with a different nucleotide base depending on the previous nucleotide base in a sequence can avoid homopolymers. For example, if the previous nucleotide is A then the ternary digit 0 may be encoded by C, the digit 1 encoded by G, and the digit 2 encoded by T. This ensures that A does not follow another A. Application and modifications of this rotating code will be readily apparent to those having ordinary skill in the art.

Thus, the nucleotide coding module 210 generates a string of letters representing nucleotide bases which encodes the same data originally represented as binary data. Depending on the volume of binary data (e.g. file size of a conventional computer file) the length of an output string from the nucleotide-encoding module 210 may be many thousands of bases long.

A segmentation module 212 divides output string from the nucleotide-encoding module 210 into a series of data blocks that each have a length that is capable of being synthesized by the oligonucleotide synthesizer 106. Currently the maximum length that can be reliably synthesized is around 200 nucleotides. However, this length is expected to change as oligonucleotide synthesis technology improves. The length of the data blocks created by the segmentation module 212 may be shorter than the maximum length capable of being synthesized in order to accommodate addition of nucleotides encoding primer binding sequences and other data in the final DNA strand. In one implementation, the length of the data blocks may be 100-150 nucleotides. Thus, the segmentation module 212 divides a long string of A, G, C, and Ts into many shorter strings. Each of the shorter strings may be referred to as an information payload.

An error-correction sequence generation module 214 generates additional nucleotide sequences that provide for error correction. Data integrity is generally provided for by adding redundancy to the DNA strands in the DNA Storage Library 102. With redundancy, if a given strand is lost entirely or if there is an error in the sequence of nucleotides in one strand, the missing or incorrect information may be identified from the redundant information.

Physical redundancy may be created by increasing the number of copies of each polynucleotide placed into a data store. However, as physical redundancy increases information density decreases. A greater number of copies of individual polynucleotides may be synthesized as one way of providing physical redundancy. In one implementation, the individual polynucleotides may be designed as partially overlapping strands that, when fully assembled, represent multiple copies of the input sequence. For example, overlapping strands may be arranged so that each nucleotide base in the input sequence is represented in four different DNA strands. This creates 4× overlap and results in an information density that is 4× lower than naïve encoding without redundancy. Naïve encoding without redundancy is simply inserting one copy of each DNA strand into the DNA Storage Library 102.

Redundancy may be provided by logical redundancy instead of or in addition to physical redundancy. Techniques for creating logical redundancy do not merely create an increased number of copies of the input sequence but add new information that can be used to generate information lost due to errors in the primary polynucleotides. One technique for creating logical redundancy is to add polynucleotides which summarize or provide partial redundancy of one or more information payloads. These additional polynucleotides may be referred to as error-correction polynucleotides. A summary sequence that is less than fully redundant modifies the original data to create a string that is shorter than the original data.

An invertible summary operation can create one or more summary sequences from a plurality of input sequences and regenerate a missing or damaged input sequence from the summary sequence and one or more other input sequences. XOR is one non-limiting example of an invertible summary operation. Invertible summary operations “summarize” inputs by creating a summary sequence that represents information from input sequences using fewer units of data (e.g., bits, trits, quats, etc.) than the sum total of the input sequences. Invertible summary operations are “invertible” because the same operation that creates the summary sequences from input sequences can also regenerate an input sequence from the summary sequence and one or more other sequences.

For example, XOR may be applied to binary data, but invertible summary operations can be applied to data encoded using base-3 or base-4. For example, an invertible summary operation may be applied to a nucleotide base sequence by assigning each of the bases an integer value from 0 to 3, taking a modulus (or “modulo”) of a summation of input values, then assigning the nucleotide base corresponding to the modulus result as the value for the summary sequence. Consider the following example.

Table 1 shows base 4 values assigned to nucleotide bases.

| x | f (x) |
|---|---|
| A | 0 |
| C | 1 |
| G | 2 |
| T | 3 |

The invertible summary operation is the base 4 modulus of the summation of the integers corresponding to the nucleotide bases. So if the input sequences have the nucleotides bases C and T, the summation of the corresponding integers is 4, the modulus of 4 (because of base-4 representation) is 1, and thus the summary sequence will include the nucleotide base C. For number 4 or larger, taking the modulus of 4 leads is the same as subtracting 4. For example 4 mod4 is 0 and 5 mod4 is 1.

C ⊕T=(f(C)+f(T))mod4=1=A

The plus inside a circle symbol “⊕” is used in the equation above to represent any invertible summary operation not only XOR. This operation has summary and invertibility properties similar to XOR. However, the same modular operation is not necessarily used to invert the result. One of ordinary skill in the art can readily extend this example to base 3 or other representations of data.

For example, if nucleotide sequence A is ACAGCA and nucleotide sequence B is TAGCTG, then taking a modulus as described above will yield the nucleotide sequence TCGTAG. Thus, the error-correction payload will contain the sequence TCGTAG.

Thus, invertible summary operations may be applied to any portion of the input data before or after conversion to a representation in nucleotide bases. The result of the invertible summary operation, the summary sequence, is the error-correction sequence that may be included in the DNA Storage Library 102.

A polynucleotide-synthesis template creation module 216 generates a string of nucleotides that is sent to the oligonucleotides synthesizer 106 for creation of a DNA strand. The information payload may represent the bulk of the polynucleotide-synthesis template, but the information payload is augmented by addition of other information.

Addressing tags are added to the information payloads so that individual DNA strands may be selectively retrieved from the DNA Storage Library 102. In its simplest form, addressing provides a key-value store, where a put(key, value) operation associates value with key, and a get(key) operation retrieves the value assigned to key. To implement a key-value interface in a DNA storage system, an index maps a key to the DNA pool 108 (in the DNA Storage Library 102) where the DNA strands that contain data reside. Amplification by the PCR thermal cycler 108 is used to selectively retrieve only desired portions of DNA from the DNA pool 108.

Each information payload may be augmented with addressing information to identify its location in the input data string. In one implementation, the address block contains two numbers: an identifier and an index. Each object has an identifier corresponding to its key in the key-value store, and the index locates the current data block within that key's value. These two numbers may be padded to fixed lengths, concatenated, and converted to nucleotides with the same representation described above. A final parity nucleotide may be added for basic error correction.

The information payloads may also be augmented with one or more primer target sequences on either end of the final DNA strand. By assigning different primers to different strands is possible to select a subset of DNA strands from the DNA pool 108. Random access can be provided by mapping the key to PCR primers, which are then used in a PCR amplification reaction performed by the PCR thermal cycler 108 that amplifies only the strands with the desired data. To read a particular key's value from the solution, PCR is performed using that key's primer, which amplifies the selected strands. The sequencing process then reads only those strands, rather than the entire pool.

After amplification, the resulting pool will have a much higher concentration of the selected strands. Taking a sample from that amplification product will likely contain only the strands that were amplified. For example, all DNA strands containing data from the same digital file may share the same primer. Because a primer is a string of 20-30 nucleotides, the theoretical space of primers is at least 4²⁰=2⁴⁰, and so the mapping from a key to its primer is comparable to a 40-bit hash function. Collisions could be handled by chaining, as in a hash table. Techniques for avoiding collisions when using 40-bit hash functions are known in the art. Analogous techniques may be applied to primers. The hash function that maps addresses to primers can be implemented as a table lookup of adapters/primers that are known to work well and have known thermocycling temperatures.

A metadata creation module 218 generates metadata that provides information about other data encoded in DNA strands. The metadata may be initially represented as binary data (similar to metadata for conventional electronic computer files) and then converted to a series of metadata payloads by the data conversion module 208, the nucleotide-encoding module 201, and the segmentation module 212.

Metadata may be used to describe how information within the data store is structured and encoded. The metadata may be stored anywhere, but storing the metadata in one or more DNA strands within the DNA Storage Library 102 ensures that it will not be separated from the DNA strands containing the information payloads. The metadata may include information on a level of redundancy present for information in the data store, the operation used to create error-correction sequences, the technique used to convert binary data into a series of nucleic acid bases, polynucleotide length, payload region length, polynucleotide type, primer targets used in for polynucleotides containing payload regions, primer targets used in error-correction polynucleotides, as well as any other information about the data store. For example, metadata may identify that XOR is used for creating error-correction sequences and there is one error-correction polynucleotide for every two primary polynucleotides. As an additional example, metadata may identify that there are two different operations used for creating error-correction sequences and that polynucleotides having a first primer site use a first one of the operations and polynucleotides having a second primer site use a second one of the operations to create the respective error-correction sequences.

The DNA Storage Library 102 will likely include millions of individual polynucleotides and extraction of metadata may be the first step in accessing information from the DNA Storage Library 102. Polynucleotides encoding metadata may be synthesized with unique primer targets that allow for selective amplification of metadata polynucleotides. The unique primer targets may be different from any other primer targets present in the DNA Storage Library 102. Therefore, amplification, by PCR or other technique, using primers that bind to these primer targets amplify only those polynucleotides containing metadata. Thus, with knowledge of the primer targets for metadata, a user can access the metadata from within the DNA Storage Library 102 and obtain additional information to make use of the data contained in the DNA Storage Library 102. The polynucleotides including metadata may also include multiple primer targets making amplification possible with multiple different primer pairs. Thus, knowledge and any one of the primer targets may be sufficient to access the metadata. These primer targets for the metadata may be recorded in any number of ways including being present in human- or machine-readable form on the outside of a container that physically holds the data store. The primer targets for metadata may also be standardized or well-known sequences such that persons of ordinary skill in the art are aware of which primers to use for accessing metadata in any data store that uses DNA.

However, a user may need some knowledge beyond the primer targets in order to access the information in polynucleotides encoding metadata. For example, the user may need to know the technique for converting the series of nucleotide bases into binary data in order to access the metadata. The user may also need to know correlations stored in a lookup table. Like the identity of the primer targets for metadata, other information used to understand the metadata may also be available in a human- or computer-readable format external to the data store. There may also be conventions or standards that specify how information is encoded in metadata for polynucleotide data stores. In some implementations, information stored within the metadata, once the primer targets are known, may be fully self-defining requiring only analysis but no additional information to interpret the metadata.

A sequence analysis module 220 receives sequence data from the DNA sequencer 112 and converts the received string of nucleotide base information (i.e., A, G, C, and Ts) into binary data that can be processed by the computing device 104 and presented on an output device such as a display. The sequence analysis module may use the addressing information contained on each DNA strand to reassemble the information payloads into the original sequence that was separated by the segmentation module 212. The hash function that maps addresses to primers and the corresponding lookup table of adapters/primers may be used by the sequence analysis module 220 to design primers for selectively accessing DNA strands from a DNA pool 108. The primer sequences may be communicated by the polynucleotide-synthesis template module 216 to the oligonucleotide synthesizer 106.

The nucleotide sequence may be converted into a base-3 or base-4 numeric sequence, which is the reverse of the operation performed by the nucleotide-encoding module 210. Finally, the numeric sequence (e.g., in base-3 or base-4) is converted back to a binary sequence. The sequence analysis module 220 may interact with the other modules (e.g., nucleotide-encoding module 210 etc.) and provide information to those modules “in reverse.” When potential errors are identified (e.g. two nucleotide sequences from the DNA sequences 106 that should be identical but are not, a DNA strand is entirely missing, etc.) data from the error-correcting payloads is referenced to determine the correct value for the potentially erroneous data. After error correction is applied, the final digital file output from the sequence analysis module should be identical to the digital data that was originally processed and placed in the DNA Storage Library 102.

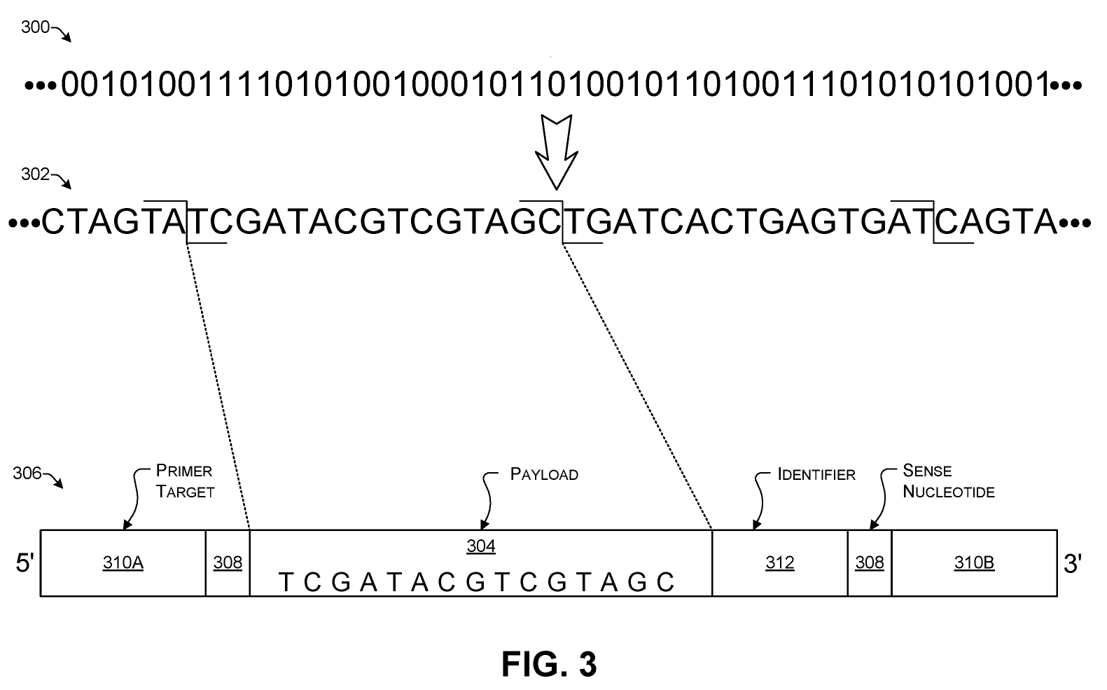

FIG. 3 shows conversion of digital data into a nucleotide sequence and insertion of that nucleotide sequence into a DNA strand. A string of binary data 300 is converted to a sequence of nucleotides 302. The binary data 300 may represent any type of information or file that is conventionally represented by binary data. For example, the binary data 300 may be a text file, an image file, an audio file, a video file, an executable file, or the like. The conversion may be performed by the nucleotide-encoding module 210 and the segmentation module 212 shown in FIG. 2. The sequence of nucleotides 302 may be a DNA sequence, an RNA sequence, or a combination of both. At this point the sequence of nucleotides 302 is electronic data, such as a text file, that contains a series of representations of DNA bases such as the letters A, G, C, and T.

The sequence of nucleotides 302 may be divided into multiple sections by the segmentation module 212. In one implementation the length of each section may be the same. Each of these sections provides the data for a payload region 304. Thus, the original binary data is divided among multiple different DNA strands 306. The DNA strands 306 may also include one or more sense nucleotides 308 to indicate whether the DNA strand 306 is reverse complemented or not.

Each of the DNA strands 306 may be present in the DNA pool 108 as a single-stranded molecule or may hybridize to a complementary ssDNA molecule to form dsDNA. The DNA strand 306 has a 5′-end sequence located on the 5′ end of the ssDNA molecule and a 3′-end sequence present on the 3′ end of the ssDNA molecule. The 5′-end sequence may include one or more known primer targets 310A. Similarly, the 3′-end sequence may also include one or more known primer targets 310B. The 5′-end primer target 310A and the 3′-end primer target 310B may have the same sequence or different sequences.

The term “primer” as used herein refers to an oligonucleotide which is capable of acting as a point of initiation of nucleic acid synthesis when placed under conditions in which synthesis of a primer product which is complementary to a nucleic acid strand is induced, i.e., in the presence of four different nucleotide triphosphates with appropriate enzymes at a suitable temperature and salt concentration. Specific length and sequence will depend on the complexity of the required DNA targets, as well as on the conditions of primer use such as temperature and ionic strength. In some implementations, a primer can be 5-50 nucleotides, 10-25 nucleotides, or 15-20 nucleotides in length. The fact that amplification primers do not have to match exactly with the corresponding template sequence to warrant proper amplification is amply documented in the literature.

An additional identifier region 312 may be included in DNA strand 306. The identifier region 312 may include information identifying the original file that was the source of the binary data 300. The identifier region 312 may also include addressing information that identifies which segment of the binary data 300 is included in the payload region 304. Thus, identifier region 312 may allow for correct reassembly of the payload regions 304 into the sequence of nucleotides 302. The identifier regions 312 may be designed so that each is sufficiently different from the others to prevent non-specific annealing under the conditions used to manipulate the DNA strands 306 in a DNA pool 108. The identifier region 312 is shown as adjacent to the 3′-end of the payload sequence 304, but the identifier region 310 may be located anywhere along the DNA molecule.

The various regions of the DNA strand 306 are not to scale. For example, the payload region 304 may be longer, that is include a greater number of DNA bases, than any of the other regions. In one implementation, payload region 304 is approximately 80 bases, each primer target 310 is approximately 20 bases, the identifier region 312 is approximately 20 bases, and the sense nucleotides 308 are each one base. This results in a total length of approximately 142 bases, which is well within the current synthesis capabilities of oligonucleotide synthesizers.

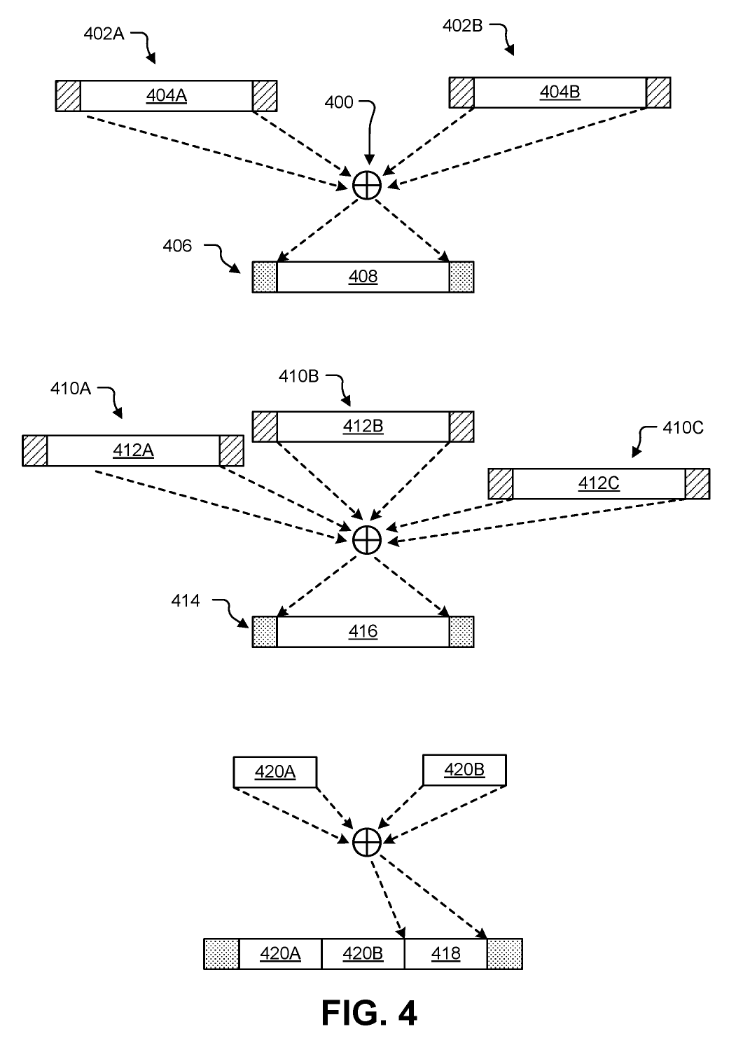

FIG. 4 shows three different techniques for creating error-correction sequences using an invertible summary operation 400. The invertible summary operation 400 is represented in FIG. 4 by the plus inside a circle symbol “⊕”. One operation that may be used to create error-correction information from information payloads is the exclusive or (XOR) operation. XOR encodes existence of a difference. When applied to binary information, the input 0, 1 or 1, 0 outputs a 1 while the input 0, 0 or 1, 1 outputs a 0. When XOR is applied to two sequences of binary information, the result has a property that upon combination with either of the input sequences in an XOR operation yields the other input sequence. For example, A XOR B=A ⊕ B, A ⊕ B XOR A=B, and A ⊕ B XORB =A. Thus, in this example A ⊕ B is a summary of A and B that contained some of the information from A and some of the information from B. A ⊕ B also creates redundancy because if either A or B are lost, that information can be regenerated using the remaining information and A ⊕ B. This redundancy is partial because A ⊕ B without more cannot provide information from either A or B.

In one implementation, primary polynucleotides 402 encode information payloads 404 that represent binary data. An invertible summary operation 400 is applied to the information payloads 404A, 404B of two primary polynucleotides 402A, 402B that creates an error-correction polynucleotide 406 with an error-correction payload 408. The invertible summary operation 400 may be applied to the binary data represented by the information payloads 404A, 404B and then converted into corresponding nucleotide sequences which become the error-correction payload 408. The invertible summary operation 400 may also be applied to the nucleotide sequences 404A, 404B by taking a modulus to generate the error-correction payload 408. Creation of the error-correcting sequence may be performed by the error-correcting sequence generation module 214 shown in FIG. 2.

This first example shows two information payloads 404A, 404B used to generate the error-correction payload 408. However, XOR or other invertible summary operation may be chained across more than two input sequences resulting in one or more error-correction sequences as shown in the next example. Thus, the XOR operation has the general properties of creating one or more error-correction sequences that are fewer in number than the input sequences (i.e., less than 2× redundancy), each error-correction sequence has less than full redundancy (i.e., at least one of the input sequences is needed to regenerate a missing or damaged sequence), and inversion by applying the same operation can regenerate at least one of the input sequences from at least one of the error-correction sequences (e.g., A can be identified from B and A ⊕ B by applying XOR to B and A ⊕ B).

The second example shows three primary polynucleotides 410A, 410B, 410C summarized using invertible summary operation 400 to generate one error-correction polynucleotide 414. Thus, the information payloads 412A, 412B, 412C are all summarized in the error-correction payload 416. This is a ratio of three input sequences to one summary sequence. A ratio of three input sequences to two output sequences (3:2) is also possible. The input sequences A, B, and C could have error correction provided by the two sequences A ⊕ B and B ⊕ C. One of ordinary skill in the art will understand that other ratios of input and error-correction sequences are possible without varying the principles described above.

For example, the ratio of input sequences to error-correction sequences could be 2:1, 3:1, 4:1, . . . n:1. For ratios in which the number of error-correction sequences is one, all but one of the total number of sequences are needed to reproduce a missing or damaged sequence. Thus, the error correction becomes less robust as the number of input sequences increases. However, the data density increases as the number of input sequences increases. Thus, it is possible to tune the level of redundancy (and also the level of data density) based on the specific technique used for creating summary sequences that provide error correction. The number of output sequences is not limited to one. Ratios of input sequences to error-correction sequences could also be 3:2, 5:2, 7:2, . . . n:m. When the ratio is 5:2, five of the seven total sequences are needed to reproduce the missing or damaged sequences.

The level of redundancy, such as the ratio of input sequences to error-correction sequences, may be adjusted based on the “importance” of the underlying data. As mentioned above, metadata may receive the highest level of error-correction and redundancy. The level of scalable redundancy may also be based on a computer-readable file type associated with the binary information contained in the information payloads. Some file types are much more tolerant of a mistake or loss of some binary data. For example, loss of a few bits of data that affect one or two pixels on a video file will likely have minimal or no impact on the user experience. However, alteration of a couple bits of data that are from a text file may result in incorrect characters in the text leading to possibly misspelled or unintelligible words.

These techniques for adjusting the level of redundancy and applying different strengths of error-correction allow for implementation at a per-block granularity. For critical data, it is possible to provide high redundancy by pairing critical blocks with many other blocks: if A is critical, produce A⊕B, A⊕C, etc. On the other hand, for blocks that are less critical, it is also possible to reduce their redundancy: instead of including only two blocks in an exclusive or, it is possible to include n, such that any n-1 of the n blocks is sufficient to recover the last, at an average data density overhead of 1/n.

Tunable redundancy is not just important for density: it also has a significant effect on performance. Both DNA synthesis and sequencing are slower and more error-prone with larger datasets, and this error does not always grow linearly in size. It is often economically viable to synthesize smaller DNA pools with more accurate technology, while larger pools are out of reach. Providing tunable redundancy allows the storage system to optimize the balance between reliability and efficiency.

In the previous two examples the error-correction sequences 408, 416 are contained in separate DNA strands 406, 414 than the input sequences (informational payloads). When this is done the DNA strands encoding error-correction payloads 406, 414 may have different primer targets than the primary polynucleotides 402, 410. Use of different primer targets allows for selectively amplifying either the polynucleotides that contain the raw information or the polynucleotides that contain redundancy information used for error correction.

However, the error-correction data does not necessarily need to be placed in a separate polynucleotide. Because the design of the error-correction sequence is done in silico by the error-correction sequence generation module 214 it is possible to arrange the information in multiple different ways and synthesize polynucleotides accordingly. One implementation includes an error-correction sequence 418 in the same DNA strand as the informational payloads 420A, 420B that are summarize by the error-correction sequence. Other configurations will also be apparent to one of skill in the art.

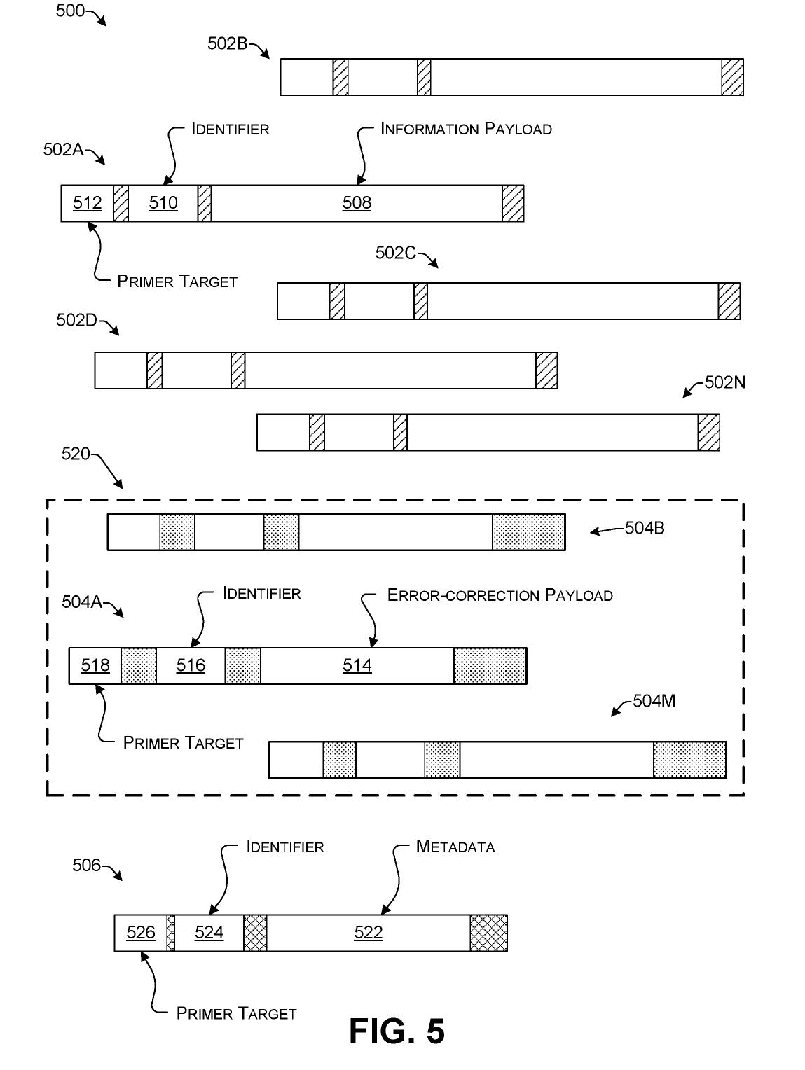

FIG. 5 shows an illustrative arrangement of DNA strands within a container 500 such as the DNA pool 108 of FIG. 1. The container 500 may contain each of the different types of DNA strands discussed previously: primary polynucleotides 502, error-correction polynucleotides 504, and metadata polynucleotides 506. The primary polynucleotides 502 may each include an information payload 508, an identifier region 510, and one or more primer targets 512. The primary polynucleotides 502 may be one implementation of the DNA strand 306 shown in FIG. 3. The container 500 will likely contain many thousands of primary polynucleotides 502A-N. Some may be identical to other primary polynucleotides 502 present in the container 500. Others may differ in the contents of the information payload 508 and identifier region 510. In one implementation, the primer target 512 may be the same for all primary polynucleotides 502.

The error-correction polynucleotides 504 include an error-correction payload 514, an identifier region 516, and one or more primer targets 518. In many implementations, there are likely to be many thousands of error-correction polynucleotides 504A-M in the container 500. In some implementations, the error-correction polynucleotides 500 may be physically separated from the primary polynucleotides 502 by being placed in a separate container 520. The separate container 520 may be a separate DNA pool 108 within the DNA Storage Library 102. The primer target 518 of the error-correction polynucleotides 504 may be different from the primer target 512 used for the primary polynucleotides 502. In this illustrative container 500, there are three error-correction polynucleotides 504A, 504B, 504M that provide error correction through redundancy for five primary polynucleotides 502A, 502B, 502C, 502D, and 502N. This represents a ratio of 5:3 of input sequences to error-correction sequences.

Finally, the container 500 may also contain one or more metadata polynucleotides 506. These polynucleotides include a metadata payload 522, an identifier 524, and one or more primer targets 526. The polynucleotides including metadata may be particularly important for maintaining usability of the DNA Storage Library 102. Loss of metadata may render the information payloads 508 unusable. Accordingly, the metadata polynucleotides 506 may be duplicated and/or subject to robust forms of error correction. Polynucleotides that include metadata may be associated with error-correction polynucleotides 504 that provide error correction for the metadata. If multiple levels of error correction are available for a given data store, the metadata polynucleotides 506 may be associated with the highest or most robust level of error correction.

The same constraints that apply to other polynucleotides also apply to metadata polynucleotides 506. Therefore, if the amount of metadata is more than can be encoded in a single synthesized polynucleotide, the metadata may be split across different polynucleotides and identified using an addressing system as described above. The identifier region 524 may contain the addressing information. The sequence of nucleotide bases that make up the metadata may be converted to binary data and analyzed as described elsewhere. Nucleotide base sequences may also provide information without conversion to binary data. Once decoded and appropriately rendered, the metadata may explain how the data store is structured with text, pictures, video etc. More compact representations of metadata may use an index or look-up table. For example, a polynucleotide encoding metadata may encode an identifier that can be cross-referenced with information stored elsewhere to identify a feature of the data store. One of example of this is that a binary code e.g. “0110” at a certain position within the string of metadata indicates that binary data is converted to base-3 data for representation as a series of nucleotide bases. Another example is a particular sequence of nucleotide bases e.g. “AGT” at a certain position within a polynucleotide indicating that binary data is converted to base-4 data prior to conversion to a series of nucleotide bases.

### Illustrative Processes

For ease of understanding, the processes discussed in this disclosure are delineated as separate operations represented as independent blocks. However, these separately delineated operations should not be construed as necessarily order dependent in their performance. The order in which the process is described is not intended to be construed as a limitation, and any number of the described process blocks may be combined in any order to implement the process, or an alternate process. Moreover, it is also possible that one or more of the provided operations is modified or omitted.

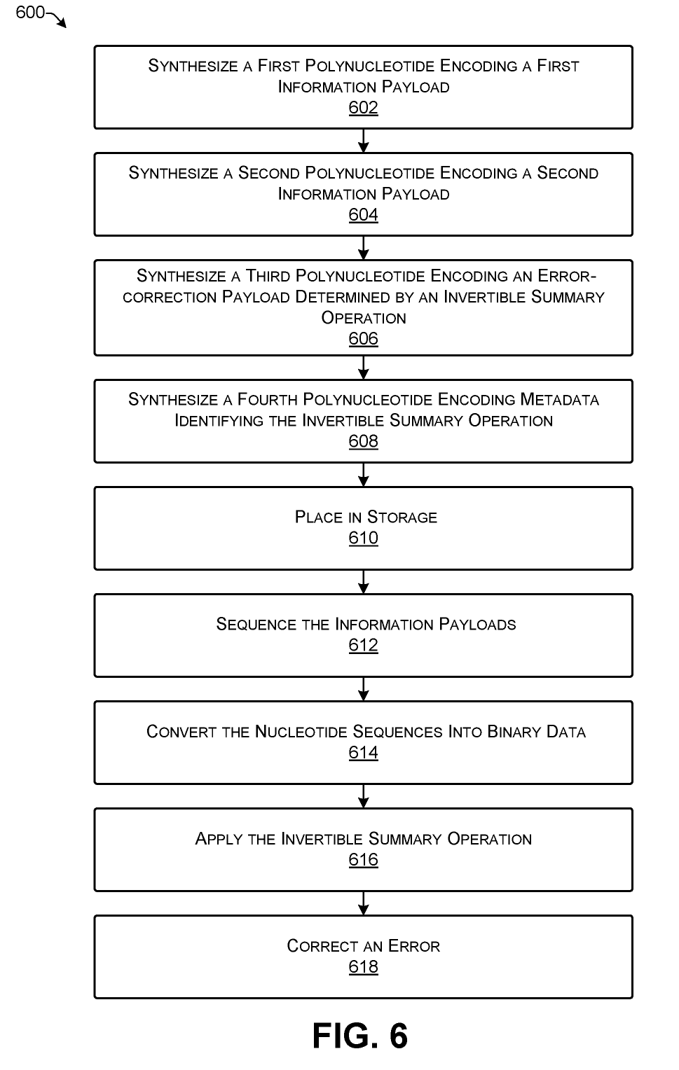

FIG. 6 shows process 600 for creating polynucleotides that contain information payloads and correcting any errors. The process 600 may be implemented by the architecture 100 shown in FIG. 1.

At 602, a first polynucleotide encoding a first information payload is synthesized. The first polynucleotide may be synthesized by the oligonucleotide synthesizer 106. The first polynucleotide may include a first address encoded in an identifier region of the first polynucleotide. The identifier region may be the same or similar to the identifier region 312 shown in FIG. 3.

At 604, a second polynucleotide encoding a second information payload is synthesized. The second polynucleotide may also be synthesized by the oligonucleotide synthesizer 106. The second polynucleotide may include a second address encoding an identifier region of the second polynucleotide. The identifier region may be the same or similar to the identifier region 312 shown in FIG. 3.

At 606, a third polynucleotide encoding an error-correction payload is synthesized. The third polynucleotide may also be synthesized by the oligonucleotide synthesizer 106. The error-correction payload has less than full redundancy of the first information payload and less than full redundancy of the second information payload. The error-correction payload is determined by an invertible summary operation on the first information payload and the second information payload. In one implementation the invertible summary operation is XOR. The identifier region of the third polynucleotide may contain a nucleotide base sequence indicating that the third polynucleotide contains an error-correction payload. The identifier region of the third polynucleotide may additionally or alternatively include the first address and the second address of the first and second polynucleotides. Inclusion of first address and second address allows for identification the polynucleotides that are summarized by the error-correction payload.

At 608, a fourth polynucleotide encoding metadata is synthesized. The metadata may identify the invertible summary operation. For example, the metadata may identify that the invertible summary operation is XOR performed on the binary data represented by the nucleotide sequences. The fourth polynucleotide may also be synthesized by the oligonucleotide synthesizer 106. In one implementation, the fourth polynucleotide may be the same or similar to the metadata polynucleotide 506 shown in FIG. 5.

At 610, the first polynucleotide, second polynucleotide, third polynucleotide, and fourth polynucleotide are place in storage such as the DNA storage library 102 shown in FIG. 1.

At 612, the first information payload, the second information payload, and the error-correction payload are sequenced. The information payloads may be sequenced by the DNA sequencer 106. Sequencing identifies a first nucleotide sequence of the first information payload, a second nucleotide sequence of the second information payload, and a third nucleotide sequence of the error-correction payload.

At 614, the first nucleotide sequence, the second nucleotide sequence, and the third nucleotide sequence are converted into a first binary data, a second binary data, and a third binary data. This conversion may be performed by one or both of the sequence analysis module 220 or the nucleotide-encoding module 210 shown in FIG. 2.

At 616, the invertible summary operation may be applied to the binary data corresponding to one of the two information payloads and the binary data corresponding to the error-correction payload. This will generate the other one of the two information payloads. For example, the summary operation may be applied to the first binary data and the third binary data to generate a second instance of the second binary data. The second instance of the second binary data should be identical to the binary data obtained from the second information payload. However if there was an error either in synthesis, sequencing, PCR amplification, or elsewhere there may be a difference between the second binary data and the second instance of the second binary data. Due to failure of PCR amplification, or other reasons, a DNA strand may be entirely absent leading to loss of one of the binary sequences. In such situations the missing binary sequence could be regenerated from the other information payload and the error-correction payload.

At 618, at least one error in the second binary data is corrected by comparing the second instance of the second binary data to the second binary data. Thus, the binary data generated by the invertible summary operation is used to identify the correct nucleotides to substitute for erroneous nucleotides (including omitted nucleotides) in the second binary data.

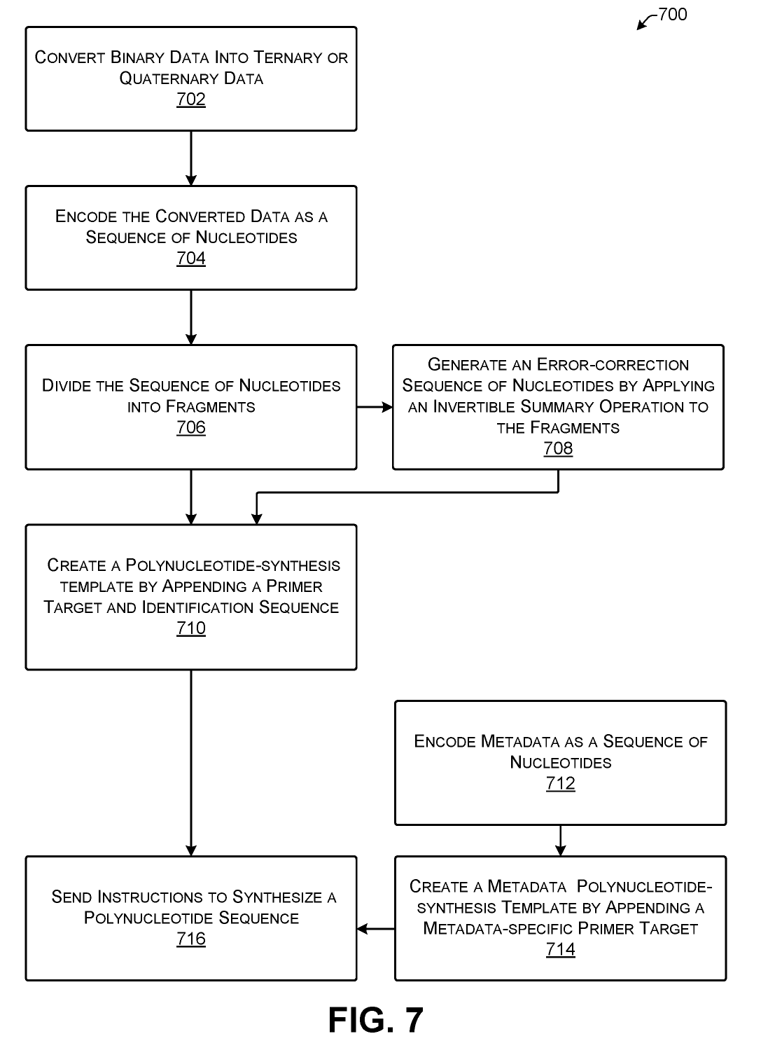

FIG. 7 shows process 700 for creating polynucleotide-synthesis templates to use for synthesis of polynucleotide sequences. The process 700 may be implemented by the computing device 104 shown in FIG. 2.

At 702, binary data is converted into ternary data or quaternary data. Following conversion, the ternary or quaternary data may be referred to as converted data. The conversion from binary data to a different type of data may be performed by the data conversion module 208.

At 704, the converted data is encoded as a sequence of nucleotide bases. The nucleotide may be DNA, RNA, or both. Conversion of a numeric string of data (e.g., binary, ternary, or quaternary) into a sequence of nucleotide bases may be performed by the nucleotide-encoding module 210. The sequence of nucleotide bases at this point is a representation of the nucleotide bases in electronic form not an actual polynucleotide.

At 706, the sequence of nucleotide bases is divided into fragments. A length a fragment may be based at least in part on a length of polynucleotide that can be synthesized by oligonucleotide synthesizer and an error rate associated with the length of polynucleotide. For example, if a 250 base polynucleotide can be synthesized but the error rate is 20% and a 200 base polynucleotide is associated with a lower error rate of 4%, the shorter polynucleotide may be the basis for the fragment lengths because of the lower error rate. Also, if a 100 base polynucleotide can be synthesized with an error rate of 0.1% and a 180 base polynucleotide can be synthesized with an error rate of 1%, the longer polynucleotide length may be used for dividing the nucleotide bases into fragments even though the error rate is slightly higher. The sequence of nucleotide bases may be divided into fragments by the segmentation module 212.

At 708, an error-correction sequence of nucleotide bases may be generated by applying an invertible summary operation to at least two of the fragments created at 706. The error-correction sequence has less than full redundancy of the at least two of the fragments—it provides partial redundancy. In one implementation, the invertible summary operation is XOR. The invertible summary operation may be applied at any of the different levels of data representation. Thus, the invertible summary operation may be applied to the binary data, to the converted data (e.g., base-3 or base-4 data), or the sequence of nucleotide bases. The error-correction sequence may be created by the error-correction sequence generation module 214.

At 710, polynucleotide-synthesis template may be created by appending a sequence of nucleotide bases representing a primer target and a sequence of nucleotide bases representing identifying information to a one of the fragments. Thus, the polynucleotide that is ultimately synthesized includes more than just a payload sequence. The additional sequences included in a DNA strand may be referred to as “overhead” which encodes data that is useful only in accessing and interpreting the data represented by the payload sequence. The polynucleotide-synthesis template may be provided by the polynucleotide-synthesis template module 216. In one implementation, the primer target may be similar or the same as a primer target 310 and the identifying information may be the same or similar as identifier region 312 shown in FIG. 3.

At 712, metadata is encoded as a sequence of nucleotide bases to create a metadata sequence. The metadata comprises data describing one or more of a level of redundancy present for information in the data store, identity of the invertible summary operation, the technique used to convert binary data into a series of nucleic acid bases, polynucleotide length, payload region length, polynucleotide type, primer targets used in primary polynucleotides, or primer targets used in error-correction polynucleotides. The metadata may be encoded by the metadata creation module 218.

At 714, a metadata polynucleotide-synthesis template is created by appending a metadata-specific primer target to the metadata sequence. In one implementation, the metadata polynucleotide-synthesis template may provide a template for synthesizing a DNA molecule such as the metadata polynucleotide 506 shown in FIG. 5.

At 716 instructions to synthesize a polynucleotide having a nucleotide sequence represented by the polynucleotide-synthesis template from 710 or 714 are sent to an oligonucleotide synthesizer. The oligonucleotide synthesizer may be the oligonucleotide synthesizer 106 shown in FIG. 1. After synthesis, the polynucleotides including the binary data encoded as the sequence of nucleotides, the error-correction sequences, and the metadata may be added to a data store such as the DNA Storage Library 102.

### EXAMPLES

To demonstrate the feasibility of DNA storage, four JPEG image files are encoded using the coding techniques described in this disclosure and the comparable error-correction technique of Goldman et al. (N. Goldman, P. Bertone, S. Chen, C. Dessimoz, E. M. LeProust, B. Sipos, and E. Birney. Towards practical, high-capacity, low-maintenance information storage in synthesized DNA. Nature, 494:77-80, 2013). These files were converted into representation stored on DNA strands and the resulting DNA was sequenced to recover the files. The results of the wet lab experiments were used to inform the design of a simulator.

Existing approaches to providing error correction for data stored in DNA sequences have focused on redundancy but have ignored density implications. The encoding proposed by Goldman uses redundancy to provide error correction by duplicating payloads of each DNA strand as a series of partially overlapping segments of the input DNA sequence, such that each nucleotide in the stream appears in four distinct strands. This encoding splits the input DNA nucleotides into overlapping segments to provide fourfold redundancy for each segment. Each window of four segments corresponds to a strand in the output encoding. Goldman has used this encoding to recover a 739 kB message with success. This encoding also offers a tunable level of redundancy, by reducing the width of the segments and therefore repeating them more often in strands of the same length to create a greater number (e.g., more than four) repetitions.

The files tested varied in size from 5 kB to 84 kB. For each image file x.jpg, DNA sequences corresponding to the output of x.jpg were generated by the techniques described above and by the techniques described in Goldman. Combined, the eight operations produced 45,652 sequences of length 120 nucleotides, representing 151 kB of data. The encoded ssDNA sequences were synthesized on microarray technology.

To demonstrate that DNA storage allows effective random access, four get operations were performed: selecting three of the four files encoded with the Goldman encoding, and one of the four encoded with the XOR encoding of this disclosure. The synthesized sequences were prepared for sequencing by amplification via PCR. The product was sequenced using an Illumina® MiSeq platform. The selected get operations totaled 16,994 sequences and 42 kB. Sequencing produced 20.8M reads of sequences in the pool. There were no reads of sequences that were not selected—so random access was effective in amplifying only the target files.

Primers for the PCR reaction were designed to amplify specific files and to incorporate sequence domains that are used for sequencing. Each primer incorporated overhangs that included three sequence domains in addition to the amplification domain necessary for PCR amplification. The first domain included the sequences necessary for binding to the Illumina® flow cell during next generation sequencing. The second domain included a custom sequencing-priming region designed for the sequencing primer to bind. This region allows for sequencing of multiple files in the same sequencing run since the sequencing primer region becomes independent of the oligonucleotide pool. These sequences were generated using Nupack software for thermodynamic analysis of interacting nucleic acid strands, in order to avoid the formation of secondary structure that could interfere with the PCR reaction. (J. N. Zadeh, B. R. Wolfe, and N. A. Pierce. Nucleic acid sequence design via efficient ensemble defect optimization. Journal of Computational Chemistry, 32(3):439-452, 2011.) The third domain consisted of a 12-nucleotide long degenerate region intended to optimize cluster detection in the Illumina® sequencing platform.

PCR amplification was performed using Platinum® PCR SuperMix High Fidelity MasterMix from Life Technologies. The cycling conditions were (i) 95° C. for 3 min, (ii) 95° C. for 20 s, (iii) 55° C. for 20 s, (iv) 72° C. for 160 s, and (v) looping through (ii)-(iv) 30 times. The PCR amplification output was purified via gel extraction and quantified before next generation sequencing. Finally, the product was sequenced using an Illumina® MiSeq sequencing platform.

All four files were successfully recovered from the sequenced DNA. Three of the files were recovered without manual intervention. One file encoded with the Goldman encoding incurred a one-byte error in the JPEG header that was fixed manually. This error was likely due to random mutation in either sequencing or synthesis.

The sequencing depth of a DNA strand is the number of times it was sequenced with a level of quality reported by the Illumina® MiSeq sequencing platform as “high quality.” Of the 20.8M reads from the sequencing run, 8.6M were “high quality” reads of a DNA strand in the desired DNA pool. The distribution of reads by sequence is heavily skewed with a mean depth of 506 reads and median depth of only 128 reads. These results suggest that encodings need to be robust not only to catch missing sequences (which get very few reads), but also to correct heavily-amplified incorrect sequences. The sequencing depth achieved in this experiment is sufficient to recover the encoded binary data. Sequencing technology can reduce sequencing depth in exchange for faster, higher-throughput results. To determine whether the tested encodings are still effective as sequencing depth reduces, random subsamples of the 20.8M reads (simulating effects of fewer reads) were used to decode one of the JPEG images, using both the Goldman and XOR encodings.

A mathematical model to estimate the nucleotide coupling efficiency determined the distribution of strand lengths produced by synthesis. The coupling efficiency is the probability that a nucleotide will be added to the strand during each of the 120 coupling cycles in the synthesis process. The model sets the likelihood of observing a strand of length n proportional to:

Intensity=nNₜpⁿ(1−p)

where Nₜ is the total number of DNA molecules being synthesized in the array, p is the coupling efficiency, and Intensity is the observed flouresence measured from gel electrophoresis. By curve fitting to this model, the nucleotide coupling efficiency in the synthesis process was estimated to be approximately 0.975.

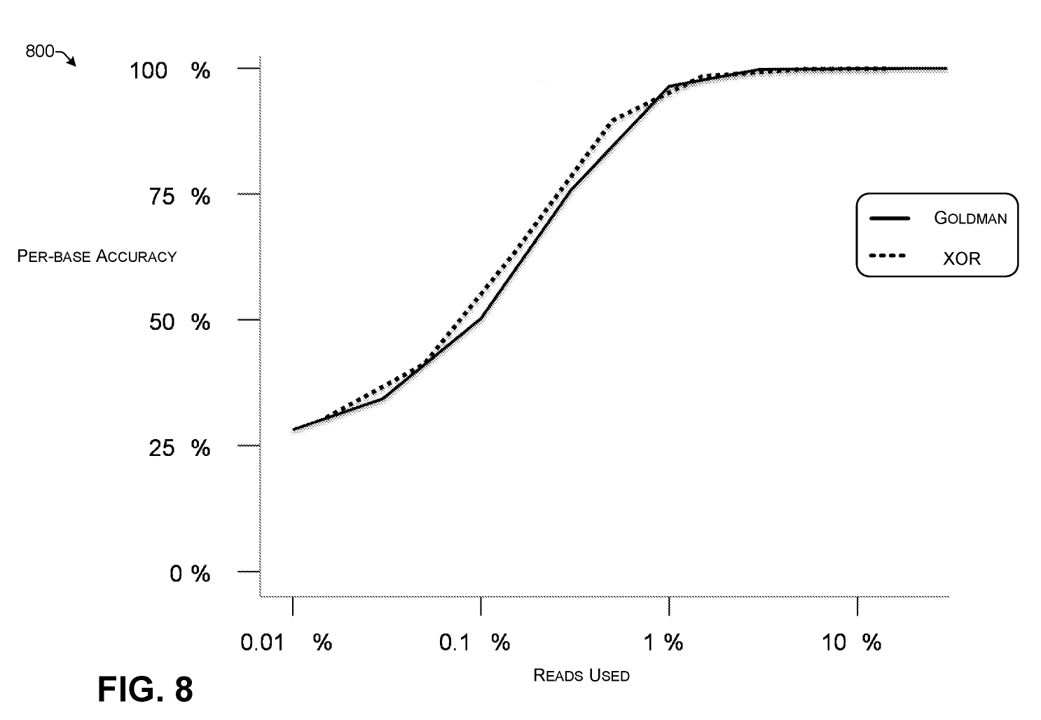

FIG. 8 shows that the Goldman and XOR encodings respond similarly to reduced sequencing depth. The x-axis plots the fraction of the 20.8M reads used, and the y-axis the accuracy of the decoded file. Both encodings achieved close to 100% per-based accuracy when slightly more than 1% of the available reads were used. In other words, they randomly selected set of approximately 200,000 reads from the 20.8M reads produced by the sequencer produce accurate results given the error-correction techniques. Both encodings tend to 25% accuracy as the depth reduces, because both decoders randomly guess one of the four nucleotides if no data is available. The accuracy of the two encodings is similar; however, the XOR encoding is higher density than the Goldman encoding as discussed below.

Naïve encoding is encoding that does not use any error correction techniques. The XOR encoding is actually a superset of a naïve encoding. Consider the first example in FIG. 4. If DNA strand 406 is ignored, only the naïvely encoded DNA strands 402A, 402B remain. Thus, by processing the sequencing data while choosing to ignore the error-correction strands it is possible to simulate the result that would be obtained with naïve encoding. A total of 11 DNA strands were missing entirely, and even after improving the decoder to arbitrarily guess the values of missing strands, it was not possible to recover a valid JPEG file. Both the XOR and Goldman encoding corrected all these errors. These results suggest that even at very high sequencing depths, naïve encoding is not sufficient for DNA storage: encodings must provide their own robustness to errors.

The results of the wet lab experiments were used to inform the design of a simulator for DNA synthesis and sequencing. The simulator allows experimenting with new encodings and new configurations for existing encodings. This section uses the simulator to answer two questions about DNA storage: first, how do different encodings trade storage density for reliability, and second, what is the effect of decay on the reliability of stored data? Both the XOR and Goldman encodings can be reconfigured to provide either higher density or higher reliability. To examine this trade-off between different encodings, a JPEG file was encoded with a variety of configurations. These configurations vary the number of strands where a piece of data is included, by changing the overlap between strands for Goldman and increasing the number of copies for XOR.

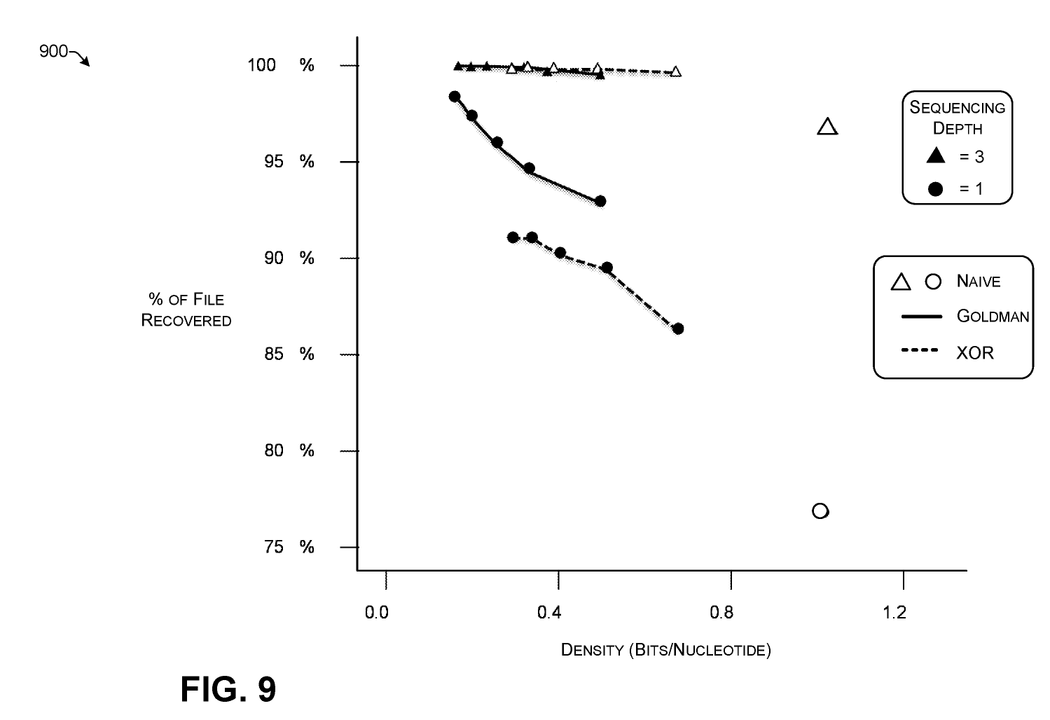

FIG. 9 plots the density achieved by an encoding (x-axis) against decoding reliability (y-axis). The density is calculated as the file size divided by the total number of bases used to encode the file. FIG. 9 includes three different encoding mechanisms: a naive encoding with no redundancy, the encoding proposed by Goldman et al., and our proposed XOR encoding. It presents the results for two sequencing depths, 1 and 3 which the data points are represented as circles and triangles respectively. Naive encoding has the lowest reliability because there is no redundancy. As the sequencing depth increases from 1 to 3, the reliability improves, but as observed in the wet lab experiments, even at higher sequencing depths, the naive encoding is not sufficient to provide full data recovery (approximately 97% of the file was recovered). For both tunable encodings, additional redundancy increases robustness, but affects density negatively. For a sequencing depth of 1, where only a single copy of each strand is available, any error causes information loss if no redundancy is available (circles). As more redundancy is added at sequencing depth of 3 (triangles), the encoding becomes more resilient to errors. At sequencing depth 1 when density is the same, Goldman is more resilient than XOR because it does not provide partial summary of bits rather it simply replicates them. At sequencing depths 3, XOR becomes as reliable as Goldman because the probability of having no copies at all of the original data lowers significantly.

Thus, when considering only accuracy and error-correction Goldman encoding and XOR encoding appear comparable. However, XOR encoding is superior in terms of data density as shown below.

One limiting factor for DNA storage is strand length: current DNA synthesis technology can only viably produce strands of lengths less than 200, and the wet lab experiments used DNA strands of length 120. But future synthesis technology is likely to increase this limit, as many fields of biology require longer artificial DNA sequences. Thus, the ratio of overhead (e.g., primer targets and identifier regions) to payload will likely decrease in the future because synthesize DNA strands will become longer. As this happens, increasing data density in the payload region will have an increasing impact on total data density in a DNA storage library. Addressing and other overheads become less significant, and density becomes a function primarly of the encoding. In a DNA strand length of 200 bases XOR encoding is approximately twice as dense as Goldman encoding with similar reliability. The density of XOR encoding may increase to 2.6× that of Goldman encoding as DNA strand length increases. The XOR encoding is two-thirds the density of naive encoding, but naive encoding suffers much worse reliability.

Thus, the use of invertible summary operations, such as XOR encoding, to create error-correction sequences provides greater data density than comparable encoding techniques and much higher reliability than naïve encoding.

### Illustrative Embodiments

The following clauses described multiple possible embodiments for implementing the features described in this disclosure. The various embodiments described herein are not limiting nor is every feature from any given embodiment required to be present in another embodiment. Any two or more of the embodiments may be combined together unless context clearly indicates otherwise. As used herein in this document “or” means and/or. For example, “A or B” means A without B, B without A, or A and B. As used herein, “comprising” means including all listed features and potentially including addition of other features that are not listed. “Consisting essentially of” means including the listed features and those additional features that do not materially affect the basic and novel characteristics of the listed features. “Consisting of” means only the listed features to the exclusion of any feature not listed.

Clause 1. A method of providing error correction for binary data encoded in synthetic polynucleotides, the method comprising:

synthesizing a first polynucleotide encoding a first information payload; synthesizing a second polynucleotide encoding a second information payload; and

synthesizing a third polynucleotide encoding an error-correction payload that has less than full redundancy of the first information payload and less than full redundancy of the second information payload, wherein the error-correction payload is determined by an invertible summary operation on the first information payload and the second information payload.

Clause 2. The method of clause 1, wherein the first polynucleotide includes a first address encoded in a first identifier region of the first polynucleotide, the second polynucleotide includes a second address encoded a second identifier region of the second polynucleotide, and the third polynucleotide includes the first address and the second address encoded in a third identifier region of the third polynucleotide.

Clause 3. The method of clause 2, wherein the third identifier region of the third polynucleotide contains a nucleotide base sequence indicating that the third polynucleotide contains an error-correction payload.

Clause 4. The method of clause 2 or 3, further comprising synthesizing a fourth polynucleotide encoding metadata identifying the invertible summary operation.

Clause 5. The method of clause 1-3 or 4, wherein the invertible summary operation includes an exclusive or operation.

Clause 6. The method of clause 1-4, or 5, further comprising:

sequencing the first information payload, the second information payload, and the error-correction payload to identify a first nucleotide sequence of the first information payload, a second nucleotide sequence of the second information payload, and a third nucleotide sequence of the error-correction payload;

converting the first nucleotide sequence, the second nucleotide sequence, and the third nucleotide sequence into a first binary data, a second binary data, and a third binary data;

applying the invertible summary operation to the first binary data and the third binary data to generate a second instance of the second binary data; and

correcting at least one error in the second binary data by comparing the second instance of the second binary data to the second binary data.

Clause 7. A system for storing binary information in synthetic polynucleotides with error correction, the system comprising:

a first number of first polynucleotides, individual ones of the first polynucleotides encoding information payloads that represent binary data; and

a second number of second polynucleotides, individuals ones of the second polynucleotides encoding error-correction payloads created by an invertible summary operation to have less than full redundancy of two or more of the information payloads.

Clause 8. The system of clause 7, wherein the first polynucleotides comprise one or more nucleotides identifying the first polynucleotides as encoding information payloads and the second polynucleotides comprise one or more nucleotides identifying the second polynucleotides as encoding error-correction payloads.

Clause 9. The system of clause 8, wherein the first polynucleotides include a first primer target, the second polynucleotides include a second primer target; and further comprising a third polynucleotide having a third primer target different than the first primer target and different than the second primer target, the third polynucleotide encoding metadata describing the first primer target and the second primer target.

Clause 10. The system of clause 7, 8, or 9, wherein the invertible summary operation includes an exclusive or operation.

Clause 11. The system of clause 7-9 or 10, wherein the second polynucleotides are physically separate from the first polynucleotides.

Clause 12. The system of clause 7-10 or 11, wherein a ratio of the first number to the second number is 2:1, 3:1, 4:1, 5:1, 3:2, or 5:2.

Clause 13. The system of clause 7-11 or 12, wherein the first number and the second number are selected based at least in part on a computer-readable file type associated with the binary information represented by the information payloads in the first polynucleotides.

Clause 14. Computer storage media comprising instructions that when executed on a processor, cause the processor to perform acts comprising:

converting binary data into converted data represented as ternary data or quaternary data;

encoding the converted data as a sequence of nucleotide bases;

dividing the sequence of nucleotide bases into fragments, wherein a length a fragment is based at least in part on a length of polynucleotide that can be synthesized and an error rate associated with the length of polynucleotide; and

generating an error-correction sequence of nucleotide bases by applying an invertible summary operation to at least two of the fragments, the error-correction sequence having less than full redundancy of the at least two of the fragments.

Clause 15. The computer storage media of clause 14, wherein the invertible summary operation is applied to one of the binary data, the converted data, or the sequence of nucleotide bases.

Clause 16. The computer storage media of clause 14 or 15, wherein the invertible summary operation includes an exclusive or operation.

Clause 17. The computer storage media of clause 14, 15, or 16, wherein the acts further comprise creating a polynucleotide-synthesis template by appending a sequence of nucleotide bases representing a primer target and a sequence of nucleotide bases representing identifying information to a one of the fragments.

Clause 18. The computer storage media of clause 17, wherein the acts further comprise sending instructions to an oligonucleotide synthesizer to synthesize a polynucleotide having a nucleotide sequence represented by the polynucleotide-synthesis template.

Clause 19. The computer storage media of clause 14-17 or 18, wherein the acts further comprise:

encoding metadata as a sequence of nucleotide bases to create a metadata sequence; and

creating a metadata polynucleotide-synthesis template by appending a metadata-specific primer target to the metadata sequence.

Clause 20. The method of clause 19, wherein the metadata comprises data describing one or more of a level of redundancy present for information in the data store, identity of the invertible summary operation, the technique used to convert binary data into a series of nucleic acid bases, polynucleotide length, payload region length, polynucleotide type, primer targets used in primary polynucleotides, or primer targets used in error-correction polynucleotides.

Clause 21. A method of maintaining metadata for a data store that stores information in synthetic polynucleotides, the method comprising:

generating a sequence for a metadata polynucleotide, the sequence including a metadata primer target;

including the metadata polynucleotide in a same container as information containing polynucleotides;

selectively amplifying the metadata polynucleotide using primers that bind to the metadata primer target but do not bind to the information containing polynucleotides thereby creating amplification product;

sequencing the amplification product to obtain sequencing results; and

comparing the sequencing results to a look-up table to identify at least one item of metadata.

### CONCLUSION

Although the subject matter has been described in language specific to structural features and/or methodological acts, it is to be understood that the subject matter defined in the appended claims is not necessarily limited to the specific features or acts described above. Rather, the specific features and acts are disclosed as example forms of implementing the claims.

All publications referenced herein are incorporated by reference both for the specific teachings for which the individual publications are cited and for everything disclosed within the referenced publications.

1. A method of providing error correction for binary data encoded in synthetic polynucleotides, the method comprising:
synthesizing a first polynucleotide encoding a first information payload;
synthesizing a second polynucleotide encoding a second information payload; and
synthesizing a third polynucleotide encoding an error-correction payload that has less than full redundancy of the first information payload and less than full redundancy of the second information payload, wherein the error-correction payload is determined by an invertible summary operation on the first information payload and the second information payload.

2. The method of claim 1, wherein the first polynucleotide includes a first address encoded in a first identifier region of the first polynucleotide, the second polynucleotide includes a second address encoded a second identifier region of the second polynucleotide, and the third polynucleotide includes the first address and the second address encoded in a third identifier region of the third polynucleotide.

3. The method of claim 2, wherein the third identifier region of the third polynucleotide contains a nucleotide base sequence indicating that the third polynucleotide contains an error-correction payload.

4. The method of claim 2, further comprising synthesizing a fourth polynucleotide encoding metadata identifying the invertible summary operation.

5. The method of claim 1, wherein the invertible summary operation includes an exclusive or operation.

6. The method of claim 1, further comprising:
sequencing the first information payload, the second information payload, and the error-correction payload to identify a first nucleotide sequence of the first information payload, a second nucleotide sequence of the second information payload, and a third nucleotide sequence of the error-correction payload;
converting the first nucleotide sequence, the second nucleotide sequence, and the third nucleotide sequence into a first binary data, a second binary data, and a third binary data;
applying the invertible summary operation to the first binary data and the third binary data to generate a second instance of the second binary data; and
correcting at least one error in the second binary data by comparing the second instance of the second binary data to the second binary data.

7. A system for storing binary information in synthetic polynucleotides with error correction, the system comprising:
a first number of first polynucleotides, individual ones of the first polynucleotides encoding information payloads that represent binary data; and
a second number of second polynucleotides, individuals ones of the second polynucleotides encoding error-correction payloads created by an invertible summary operation to have less than full redundancy of two or more of the information payloads.

8. The system of claim 7, wherein the first polynucleotides comprise one or more nucleotides identifying the first polynucleotides as encoding information payloads and the second polynucleotides comprise one or more nucleotides identifying the second polynucleotides as encoding error-correction payloads.

9. The system of claim 8, wherein the first polynucleotides include a first primer target, the second polynucleotides include a second primer target; and
further comprising a third polynucleotide having a third primer target different than the first primer target and different than the second primer target, the third polynucleotide encoding metadata describing the first primer target and the second primer target.

10. The system of claim 7, wherein the invertible summary operation includes an exclusive or operation.

11. The system of claim 7, wherein the second polynucleotides are physically separate from the first polynucleotides.

12. The system of claim 7, wherein a ratio of the first number to the second number is 2:1, 3:1, 4:1, 5:1, 3:2, or 5:2.

13. The system of claim 7, wherein the first number and the second number are selected based at least in part on a computer-readable file type associated with the binary information represented by the information payloads in the first polynucleotides.

14. Computer storage media comprising instructions that when executed on a processor, cause the processor to perform acts comprising:
converting binary data into converted data represented as ternary data or quaternary data;
encoding the converted data as a sequence of nucleotide bases;
dividing the sequence of nucleotide bases into fragments, wherein a length a fragment is based at least in part on a length of polynucleotide that can be synthesized and an error rate associated with the length of polynucleotide; and
generating an error-correction sequence of nucleotide bases by applying an invertible summary operation to at least two of the fragments, the error-correction sequence having less than full redundancy of the at least two of the fragments.

15. The computer storage media of claim 14, wherein the invertible summary operation is applied to one of the binary data, the converted data, or the sequence of nucleotide bases.

16. The computer storage media of claim 14, wherein the invertible summary operation includes an exclusive or operation.

17. The computer storage media of claim 14, wherein the acts further comprise creating a polynucleotide-synthesis template by appending a sequence of nucleotide bases representing a primer target and a sequence of nucleotide bases representing identifying information to a one of the fragments.

18. The computer storage media of claim 17, wherein the acts further comprise sending instructions to an oligonucleotide synthesizer to synthesize a polynucleotide having a nucleotide sequence represented by the polynucleotide-synthesis template.

19. The computer storage media of claim 14, wherein the acts further comprise:
encoding metadata as a sequence of nucleotide bases to create a metadata sequence; and
creating a metadata polynucleotide-synthesis template by appending a metadata-specific primer target to the metadata sequence.

20. The method of claim 19, wherein the metadata comprises data describing one or more of a level of redundancy present for information in the data store, identity of the invertible summary operation, the technique used to convert binary data into a series of nucleic acid bases, polynucleotide length, payload region length, polynucleotide type, primer targets used in primary polynucleotides, or primer targets used in error-correction polynucleotides.


SEQUENCE LISTING (1 sequence)

SEQ ID NO: 1 - DNA, 41 bp, Artificial Sequence
  synthetic sequence for illustration only
ctagtatcgatacgtcgtagctgatcactgagtgatcagta